(19) United States
(12) Patent Application Publication
(10) Pub. No.: US 2011/0042647 A1
(43) Pub. Date: Feb. 24, 2011

(54) CORRUGATED-QUANTUM WELL INFRARED PHOTODETECTOR WITH REFLECTIVE SIDEWALL AND METHOD

(75) Inventor: KWONG-KIT CHOI, Brookeville, MD (US)

Correspondence Address: U S ARMY RESEARCH LABORATORY;ATTN: RDRL-LOC-I, 2800 POWDER MILL RD, ADELPHI, MD, 20783-1197, US

(73) Assignee: U.S. Government as represented by the Secretary of the Army, Adelphi, MD (US)

(21) Appl. No.: 12/543,121

(22) Filed: Aug. 18, 2009

(51) Int. Cl. H01L 31/0352; H01L 31/18

(52) U.S. Cl. 257/21; 438/72; 257/E31.033; 257/E21.211

(57) ABSTRACT

A quantum well infrared photodetector comprising a tunable voltage source; first and second contacts operatively connected to the tunable voltage source; a substantially-transparent substrate adapted to admit light; first and second layers operatively connected to the first and second contacts; a quantum well layer positioned between the first and second layers; light admitted through the substantially transparent substrate entering at least one of the first and second layers and passing through the quantum well layer; at least one side wall adjacent to at least one of the first and second layers and the quantum well layer; the at least one side wall being substantially non-parallel to the incident light; the at least one sidewall comprising reflective layer which reflects light into the quantum well layer for absorption. A preferred method for improving the reflectivity of a quantum well infrared photodetector comprises forming a first sidewall layer on the sidewalls of the corrugated quantum well infrared photodetector; forming a second sidewall layer on the sidewalls of the corrugated quantum well infrared photodetector; the second sidewall layer being formed of a reflective material and the first sidewall layer operating to electrically isolate the reflective material from at least one of the first and second contact layers; whereby the reflective metal operates to reflect light rays into corrugated quantum well infrared photodetector device and to substantially prevent infrared rays in environment from entering through the sidewalls.

### GOVERNMENT INTEREST

The invention described herein may be manufactured, used, and/or licensed by or for the United States Government.

### FIELD OF THE INVENTION

This invention relates generally to semiconductor crystals, and more particularly to quantum well structures.

### BACKGROUND OF THE INVENTION

The present invention relates to corrugated-quantum well infrared photodetectors (C-QWIPs) for long wavelength infrared detection. Detector structure may be optimized in the production of a number of large focal plane arrays (FPAs). C-QWIP cameras, for example, can be made in higher resolution, in larger production volume, at a lower cost, in higher sensitivity, in broadband and multi-color detection. Corrugated-QWIP utilizes optical reflections to change the direction of light inside the pixel. A C-QWIP pixel structure is shown in FIGS. 2A and 2B. The structure was originally patented by Choi in U.S. Pat. No. 5,485,015, hereby incorporated by reference, entitled “Quantum Grid Infrared Photodetector,” which discloses a quantum grid infrared photodetector (QGIP) that includes a semiconductor substrate with a quantum well infrared photodetector (QWIP) mounted thereon. U.S. Pat. No. 5,217,926 to Choi, hereby incorporated by reference discloses voltage-tunable detection. U.S. Pat. No. 7,217,926, hereby incorporated by reference, discloses “Systems involving voltage-tunable quantum-well infrared photodetectors.” Under this light coupling approach, a number of V-grooves are etched into the layered material to create angled mesa sidewalls. The inclined sidewalls reflect normal incident light into large angle propagation as shown in FIG. 2B. The light reflection is based on total internal reflection when the light impinges on a surface at an angle that is larger than the critical angle. For the present material that is made of GaAs whose refractive index is 3.34, the critical angle will be 17.4° when the material is in contact with air or vacuum. Since the sidewall angle is 50°, the angle of incidence for normal incident light will also be 50°, making it larger than the critical angle. The light will thus be totally internal reflected and be absorbed by the detector material.

Uses of Infrared cameras include night vision, missile intercept, infrared astronomy, natural resources exploration, industrial quality control, and medical imaging. Commercial Quantum well infrared photodetectors (QWIPs) have emerged as a mainstream technology for long wavelength infrared detection and are more economical than tradition Mercury Cadmium Telluride (HgCdTe) materials, but the grating coupled detectors are not as sensitive. Utilizing the mature gallium arsenide material technology, QWIP focal plane array (FPA) cameras are amenable for low cost and high volume production. Today, QWIP cameras with resolution as high as 640×512 pixels are commonly available in the commercial market. However, QWIP technology is still evolving and improvements can be made.

QWIP cameras are available from commercial vendors such as FLIR and Qmagiq. To enable normal incident detection, each pixel is equipped with a reflective grating on top to scatter light, which is incident from below. A cross-section of two pixels in an array is shown in FIG. 1. In the presence of a grating with a particular period, the light with certain wavelengths will diffract at a large angle. Travelling at an oblique angle, the light can be partially absorbed by the material and photocurrent inside the pixel is generated. As illustrated in FIG. 1, QWIPs are infrared detectors that are made of layers of quantum well (QW) materials. These QW materials have a unique property that they are sensitive to light only when the light is propagating parallel to these layers. When the light is incident normally upon the layers, the materials are unable to absorb and detect light. In an imaging detector array, detector pixels are fabricated on these layered material structures. When the array is facing a scene, the light from the scene will enter into the detector pixel normally, making the detection impossible without an enabling light coupling means.

Generally, QWIP material absorbs light only when the optical electric field is vertical to the material layers. To detect light under normal incidence, the conventional approach is to use diffraction gratings. Grating coupled QWIP FPAs are expensive due to the low yield in grating fabrication; less sensitive due to inefficient, narrow band light coupling; lower in definition due to the larger pixel size. While diffraction gratings offer a useful approach, high diffraction efficiency is nevertheless difficult to achieve over a limited pixel area. Furthermore, a study by De Rossi, et al., entitled “Effects of finite pixel size on optical coupling in QWIPs,” Inf. Phys. and Tech., vol. 44, pp.325-330, 2003, showed that when the pixel size is less than 25 microns across, the entire pixel volume can act as a resonant cavity in defining the overall electromagnetic (EM) field. A small change in the pixel geometry or substrate thickness can change the detector quantum efficiency η drastically. Although large η has been reported in Andersson, et al, “Near-unity quantum efficiency of AlGaAs/GaAs quantum well infrared detectors using a waveguide with a doubly periodic grating coupler,” Appl. Phys. Lett., vol. 59, pp. 857-859, (1991), using the grating approach, there is little evidence that high performance can be reliably achieved given the normal manufacturing tolerances.

To improve the optical coupling in QWIPs, corrugated-quantum well infrared photodetectors (C-QWIPs) have been proposed and studied in Chen, et al. “Corrugated quantum well infrared photodetectors for normal incident light coupling,” Appl. Phys. Lett., vol. 69, pp. 1446-1448 (1996) and Choi, et al., “Corrugated quantum well infrared photodetectors for material characterization.” J. Appl. Phys., vol. 88, pp. 1612-1623 (2000). The detector uses total internal reflection at the inclined mesa sidewalls to reflect light into parallel propagation and creates the vertical field. Rigorous EM field simulations indicate that resonant cavity effects do not play a role in this detector structure, see Yan, et al., “Electromagnetic modeling of quantum-well photodetectors containing diffractive elements,” IEEE J. Quantum Electron., vol. 35, pp. 1870-1877 (1999) and Choi, et al., “Light coupling characteristics of corrugated quantum well infrared photodetectors,” IEEE J. of Quan. Electr., vol. 40, pp. 130-142 (2004).

Adopting C-QWIPs in FPA production is potentially advantageous both in performance and in manufacturability. Because reflection is more effective in redirecting the light, η is larger. Reflection is also independent of wavelength. This means that the detector will preserve the natural absorption spectrum of the material, which often can be much wider than the grating coupling bandwidth. Without the need for matching the material wavelength to the grating cavity modes in the detector, the same pixel geometry and production process are applicable to all QWIP material designs. This allows the simultaneous production of FPAs having a wide range of wavelength bands without jeopardizing η. In the absence of the fine grating features, it also allows the use of standard photolithographic techniques for faster, less expensive and very large format production. With all these benefits, QWIP technology can be further improved for high-sensitivity and high-resolution imaging. A “bare” C-QWIP detector however is subjects to adverse effects from its surrounding. Any material came in contact with the detector will change the sidewall reflectivity and thus its η. In order to guarantee the high performance irrespective to the production process, a designated cover layer for sidewall encapsulation is needed.

By way of background, FIG. 2A, which was extracted from U.S. Pat. No. 7,217,926, shows a 3-dimensional perspective of a suggested C-QWIP detector pixel, which contains a number of corrugations and a central island for external electrical contact. FIG. 2B shows the cross-section containing three corrugations and a light path showing total internal reflection. Although this detector structure had been studied experimentally and shown to be effective in individual detectors (C. J. Chen et al. “Corrugated quantum well infrared photodetectors for normal incident light coupling”, Applied Physics Letters, vol. 69, 1446, 1996), the detectors were found to be less sensitive when they were integrated with readout integrated electronic circuits (ROlCs) in focal plane array (FPA) cameras. The apparent cause of the deficiency appears to be the reduction of sensitivity due to the presence of backfill materials on top of the detector V-grooves in the FPAs. In the FPA production process, an epoxy material is applied between the detector array and the ROIC to bind them together, as shown in FIG. 3. The epoxy backfill strengthens the mechanical properties of the array but it also alters the optical reflection at the detector/epoxy interface.

To evaluate the effects of the epoxy materials, which can have a wide range of infrared absorption properties, the sidewall reflectivity is calculated as a function of the complex refractive index of the epoxy N=n+ik, where n is the real part of the refractive index and k is the extinction coefficient. While the typical n for epoxy is 1.5, k can vary within a wide range of values depending on the types of epoxy. For generality, FIG. 4 shows the calculated sidewall reflectivity R as a function of the extinction coefficient k. R can reduce from 100% to 25% at certain k for the p-polarized light, the polarization component that is responsible for C-QWIP infrared absorption. Therefore, the presence of epoxy can reduce the sidewall reflection by a factor of 4.

### SUMMARY OF THE INVENTION

To enhance the sidewall reflectivity, and to isolate the detector from its surroundings (e.g., epoxy), in accordance with a preferred embodiment of the present invention, a cover layer is deposited on the sidewalls to isolate the detector material from the surrounds (which may be for example epoxy). Preferably, the cover layer provides reflectivity that is close to the original total internal reflection and is arranged so that it does not short out the electrical contacts located on top and bottom of the QWIP material.

A preferred embodiment of the present invention comprises apparatus and methodology for increasing reflectivity and, therefore, efficiency of a corrugated quantum well infrared photodetector. A preferred embodiment is a composite layer encapsulated corrugated quantum well infrared photodetectors (CLE C-QWIPs). In the preferred embodiment, a composite layer having high reflectivity ensures the high η of the C-QWIP arrays, while the low leakage of a dielectric layer, which may be MgF₂, will not increase the detector dark current. For example, the reflective layer may comprise a high plasma energy layer of gold and the dielectric layer may comprises a material having low optical phonon energy such as MgF₂ in order to provide a large wavelength window for high reflectivity of the film. Utilizing a composite layer of a MgF₂/Au film, for example, is easy to apply, fast and economical; and will not substantially add cost to the array production. A further advantage is that the detector shielding will substantially eliminate (or reduce, depending upon the layer thickness) the effects of infrared absorbing materials surrounding the detector(s).

A preferred embodiment pixel structure is shown in FIG. 5. Each detector pixel in this preferred embodiment may comprise an active material with thickness tₐ, a top contact layer 1 having a thickness t_{c}, and a bottom contact layer 4 having a thickness t_{b}. The total thickness t=tₐ+t_{b}+t_{c}. The top contact layer 1 may have a different sidewall angle. The active layer 2 sidewall is preferably inclined at 45°, making the average mesa sidewall angle of 50° in the embodiment shown in FIG. 5. The mesa sidewall of the invention is covered by a protective layer. Underneath the structure, there is a common contact layer connecting all the detectors. The corrugation period p is designed to be the same as the pixel pitch in the one-corrugation-per-pixel design. This design is preferred in high definition arrays in which pixel size is small. As shown in FIG. 5, a cover layer 7 is deposited on the sidewalls to isolate the detector material from the epoxy and provide reflectivity. Preferably, the reflectivity provided is close to the original total internal reflection and the cover layer 7 does not short out the electrical contacts that are located on top and bottom of the Q WIP material.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The present invention can best be understood when reading the following specification with reference to the accompanying drawings, which are incorporated in and form a part of the specification, illustrate alternate embodiments of the present invention, and together with the description, serve to explain the principles of the invention. In the drawings:

FIG. 1 is an illustration of grating coupled QWIPs adopted in commercial QWIP cameras. The grating period is a+b, and the grating groove height is h. The values of a, b and h determine the diffraction angle θ of a particular wavelength.

FIG. 2A illustrates a 3-dimensional perspective of a C-QWIP detector pixel, which contains a number of corrugations and a central island for external electrical contact.

FIG. 2B illustrates a partial cross-section of the embodiment shown in FIG. 2A showing three corrugations and a light path showing total internal reflection.

FIG. 3 is an illustration of the cross-section of a detector array hybridized to a readout circuit. The voids between the array and the ROIC are filled with epoxy binding materials.

FIG. 4 is a graphical representation showing the sidewall reflectivity plotted as a function of the extinction coefficient of the epoxy backfill material.

FIG. 5 illustrates the cross-section of two CLE C-QWIP pixels wherein the sidewalls are covered with a designed protective layer.

FIG. 6A is a typical energy diagram of a n-type QWIP along the growth (z) axis. In this figure, the wells are made of GaAs/InGaAs/GaAs layers. E₃ to E₆ are the resonant QW states. The shaded region above the barriers is the global conduction band.

FIG. 6B is a graphical illustration wherein the dashed curves show the individual fₙρₙ(λ) assuming σₙ=n+4 meV. The solid curve shows the combined oscillator strength f(λ). The straight line shows the wavelength λ_{H} that divides the bound-to-bound and bound-to-continuum transitions. The right y-axis shows the corresponding absorption coefficient for N_{D} of 1×10¹⁸ cm⁻³.

FIG. 6C is a top view of C-QWIP pixels in an array. Shown in gold are the metal reflecting layers 7 of the C-QWIP.

FIG. 6D shows the complex refractive indices, N=n+ik, of MgF₂ and Au films as a function of wavelength.

FIG. 6E graphically illustrates the calculated sidewall reflectivity R for different Au thicknesses. The p-polarized light is responsible for QWIP absorption. The s-polarized light is not coupled under the present corrugated coupling.

FIG. 7 illustrates the calculated sidewall reflectivity R for different MgF₂ thicknesses. The inset shows R in an expanded scale. The inset of FIG. 7 shows R is generally larger than 0.95 for any t_{d}, and when t_{d}=1 μm, R becomes effectively unity within a wide wavelength range.

FIG. 8 illustrates the calculated η(λ) of a C-QWIP having α shown in FIG. 6B.

FIG. 9 shows the η reduction factor κ as a function of tₐ. The circles are from EM field simulation, and the curve is a fit to this simulation. For a given tₐ<11 μm, η(tₐ)=κη₀.

FIG. 10 graphically illustrates the pixel current density (symbols) at each V is plotted against T_{B}. The solid curves are fittings to the data using J_{d} and CE as fitting parameters.

FIGS. 11(a), 11(b), 11(c) and 11(d) show the calculated responsivity for each individual state, their combined spectrum, and the measured spectrum for focal plane arrays LC1, LC2, LC5 and LC6, respectively. The straight line divides the transitions below and above the barrier height.

FIG. 12 graphically illustrates the measured gain of the detectors at 77 K.

FIG. 13 shows the LC2 FPA η (squares) and CE (circles) as a function of V. The dashed curve shows the background photocurrent of a single test detector in arbitrary units.

FIG. 14 shows the LC5 CE for the fan-out (circles) and the FPA (diamonds). The dashed curve shows the background photocurrent of a test detector in arbitrary unit. The figure also shows η of the fan-out (squares).

FIG. 15 shows LC6 FPA η (squares) and CE (circles). The dashed curve shows the background photocurrent of a test detector in arbitrary unit.

FIG. 16 graphically illustrates the observed η (circles) plotted against the predicted values. The dash line represents prefect agreement.

FIG. 17 is a graphical illustration plotting normalized QE versus wavelength depicting the spectral response or the η spectrum of the LC4 FPA (not described further herein) and the test detector at V=2V.

FIG. 18 is an image taken by a 1024×1024 LC5 focal plane array (FPA).

FIG. 19 illustrates the normalized spectral responsivity of four detectors considered in the system analysis.

FIGS. 20(a), 20(b), 20(c) and 20(d) illustrate the calculated quantum efficiency, assumed gain, and the calculated conversion efficiency as a function of N_{w} inside the corrugation for four different FPA detector designs.

FIGS. 21(a), 21(b), 21(c) and 21(d) illustrate the respective NEΔT at different operating temperature T when N_{w}>60, all the FPAs can achieve an NEΔT below 20 mK at T between 60 - 70 K. FIGS. 21(a), 21(b), 21(c) and 21(d) illustrate the calculated NEΔT of the four designed FPAs as a function of operating temperature assuming n_{rd}=900e⁻, and p=25 μm.

FIGS. 22(a), 22(b), 22(c) and 22(d) graphically illustrate the projected NEΔT as a function of n_{rd} for the four FPA designs.

FIGS. 23(a), 23(b), 23(c) and 23(d) graphically illustrate the number of collected electrons as a function of operating temperature for the four FPA designs.

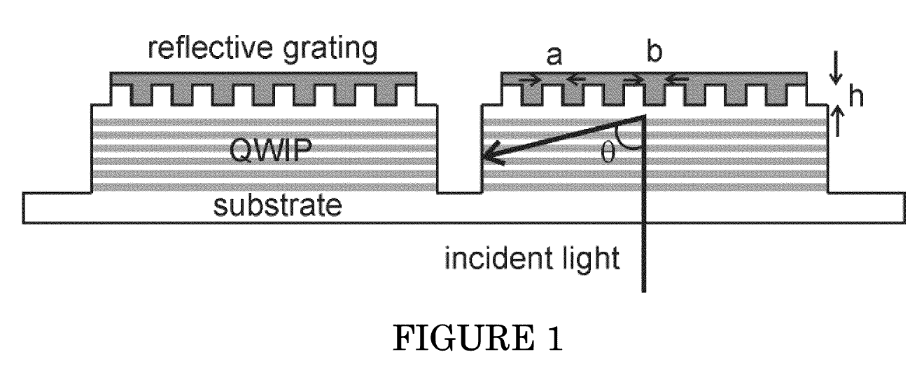

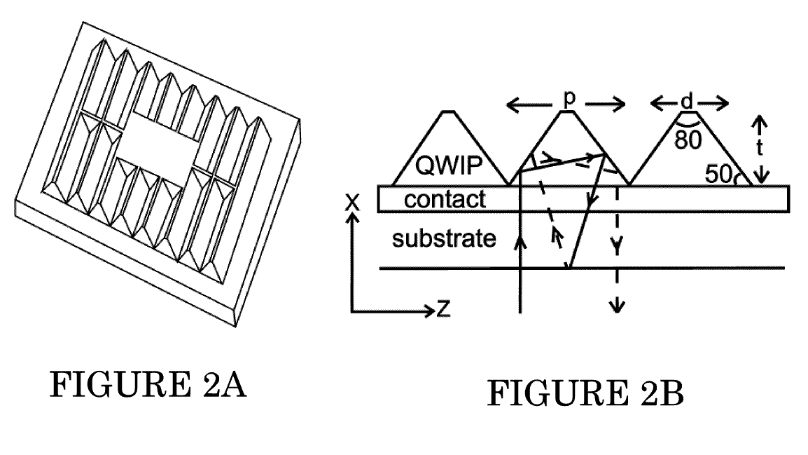

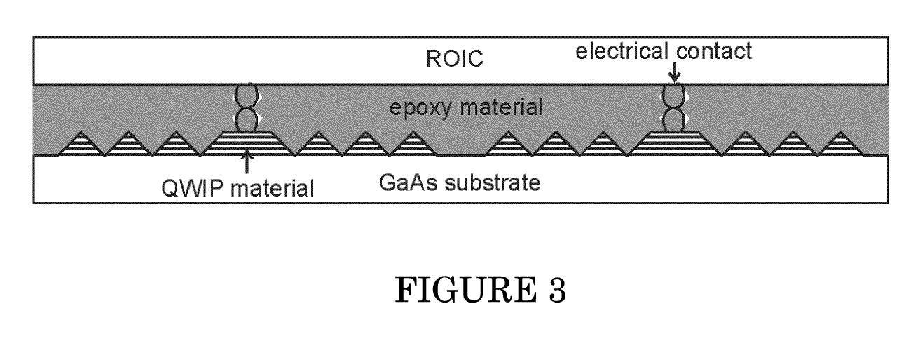

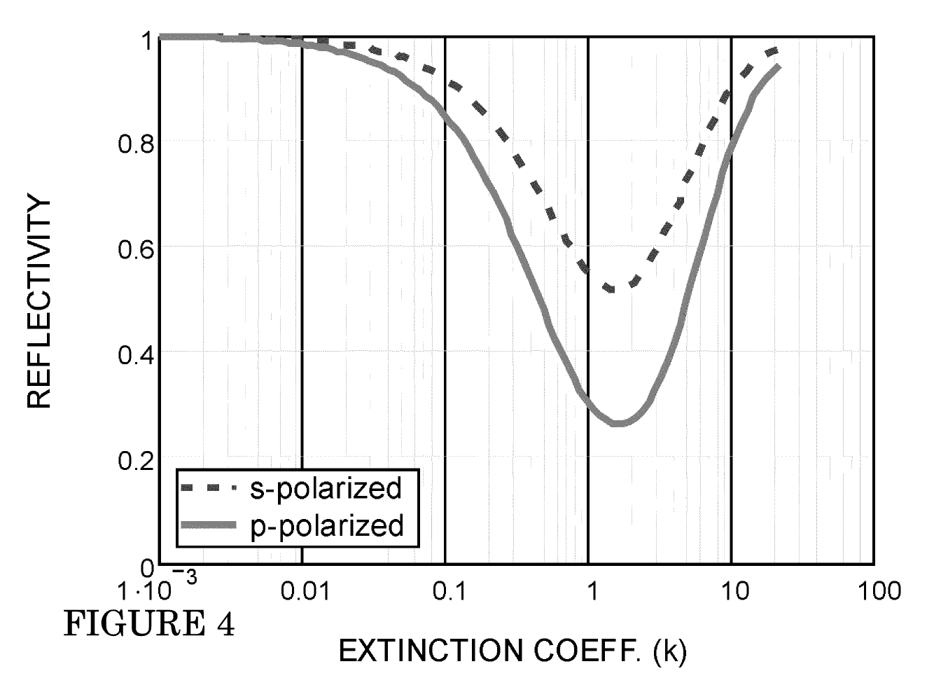

A more complete appreciation of the invention will be readily obtained by reference to the following Description of the Preferred Embodiments and the accompanying drawings in which like numerals in different figures represent the same structures or elements. The representations in each of the figures are diagrammatic and no attempt is made to indicate actual scales or precise ratios. Proportional relationships are shown as approximates.

### DETAILED DESCRIPTION OF THE PREFERRED EMBODIMENTS

The present invention now will be described more fully hereinafter with reference to the accompanying drawings, in which embodiments of the invention are shown. However, this invention should not be construed as limited to the embodiments set forth herein. Rather, these embodiments are provided so that this disclosure will be thorough and complete, and will fully convey the scope of the invention to those skilled in the art. In the drawings, the thickness of layers and regions may be exaggerated for clarity. Like numbers refer to like elements throughout. As used herein the term “and/or” includes any and all combinations of one or more of the associated listed items.

The terminology used herein is for the purpose of describing particular embodiments only and is not intended to limit the full scope of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Furthermore, relative terms, such as “lower” or “bottom” and “upper” or “top,” may be used herein to describe one element's relationship to other elements as illustrated in the Figures. It will be understood that relative terms are intended to encompass different orientations of the device in addition to the orientation depicted in the Figures. For example, if the device in the Figures is turned over, elements described as being on the “lower” side of other elements would then be oriented on “upper” sides of the other elements. The exemplary term “lower”, can therefore, encompass both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below. Furthermore, the term “outer” may be used to refer to a surface and/or layer that is farthest away from a substrate.

Embodiments of the present invention are described herein with reference to cross-section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an etched region illustrated as a rectangle will, typically, have tapered, rounded or curved features. Thus, the regions illustrated in the figures are schematic in nature and their shapes are not intended to illustrate the precise shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will also be appreciated by those of skill in the art that references to a structure or feature that is disposed “adjacent” another feature may have portions that overlap or underlie the adjacent feature.

A preferred embodiment of the present invention comprises apparatus and methodology for increasing reflectivity and, therefore, efficiency of a corrugated quantum well infrared photodetector. A preferred embodiment comprises a composite layer 7 which provides substantial encapsulation of the corrugated quantum well infrared photodetectors (CLE C-QWIPs) in order to provide sidewall reflectivity and shield the detector from the presence of infrared absorbing materials in its surrounding. Preferably, this layer structure provides reflectivity that is close to the original total internal reflection, and does not short out the electrical contacts that are located on top and bottom of the QWIP material. The composite layer preferably comprises a first material having high reflectivity that ensures the high QE of the C-QWIP arrays, and a second material having low leakage, such as for example a dielectric, which will not increase the detector “dark” current. For example, the first material may be a reflective layer of gold and the second material may be a dielectric layer formed of a material having a low optical phonon energy such as MgF₂. The composite layer provides a large wavelength window for high reflectivity. The deposition of the composite layer, such as an MgF₂/Au film, may be simple, fast and economical, and not add substantial cost to the array production.

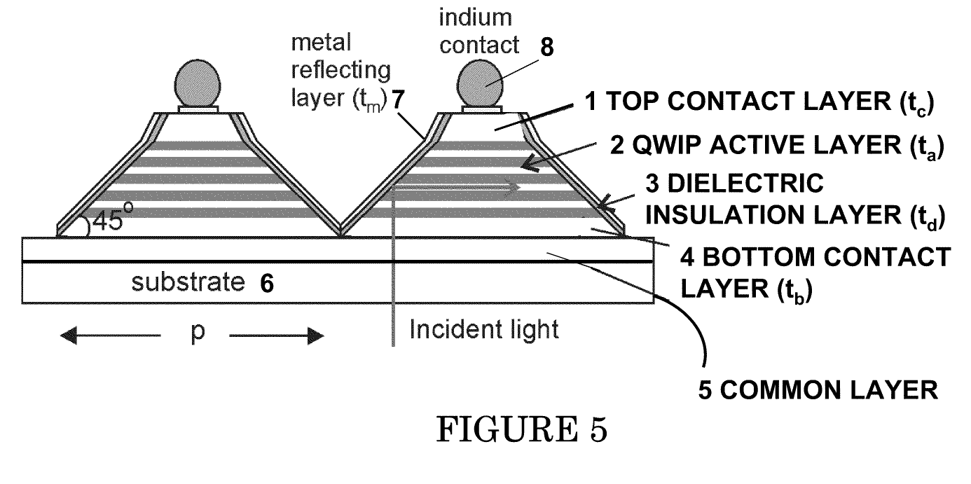

A preferred embodiment pixel structure is shown in FIG. 5, wherein the cross-section of two CLE C-QWIP pixels is illustrated. Each detector pixel in this preferred embodiment comprises an active material with thickness tₐ, a top contact layer 1 having a thickness t_{c}, and a bottom contact layer 4 having a thickness t_{b}. The total thickness t=tₐ+t_{b}+t_{c}. The top contact layer 1 can have a different sidewall angle. The active layer 2 sidewall is preferably inclined at 45°, making the average mesa sidewall angle of 50° in this example. The mesa sidewall of the invention is covered by a protective layer. Underneath the structure, there is a common contact layer connecting all the detectors. The corrugation period p is designed to be the same as the pixel pitch in the one-corrugation-per-pixel design. This design is preferred in high definition arrays in which pixel size is small.

In a preferred embodiment structure, a composite layer comprising magnesium fluoride (MgF₂) and gold (Au) is selected. The dielectric material MgF₂ layer is used to electrically isolate the gold layer from shorting the top and bottom contacts. MgF₂ is chosen for its high dielectric strength (breakdown voltage =16 V for a 1000 Å thick film), low conducting current (=1×10⁻⁸ A/cm² at 6 V direct bias for a 4400 Å thick film), low refractive index, and small extinction coefficient. The gold layer is chosen for its high reflectance. The present invention is not limited to gold and MgF₂. Any materials with similar characteristics can be used. Examples are zinc sulfide, zinc selenide, calcium fluoride, barium fluoride, silicon nitride and silicon dioxide for the dielectric layer, and silver and chromium for the metal layer.

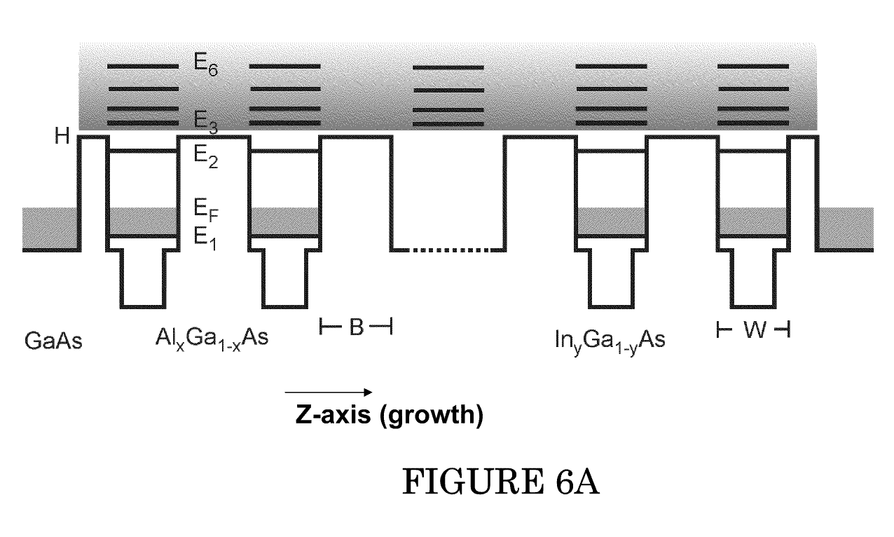

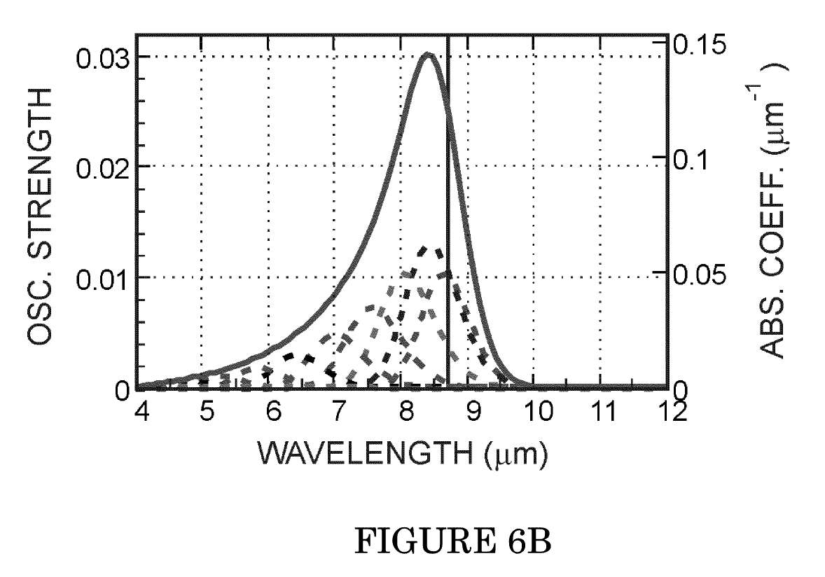

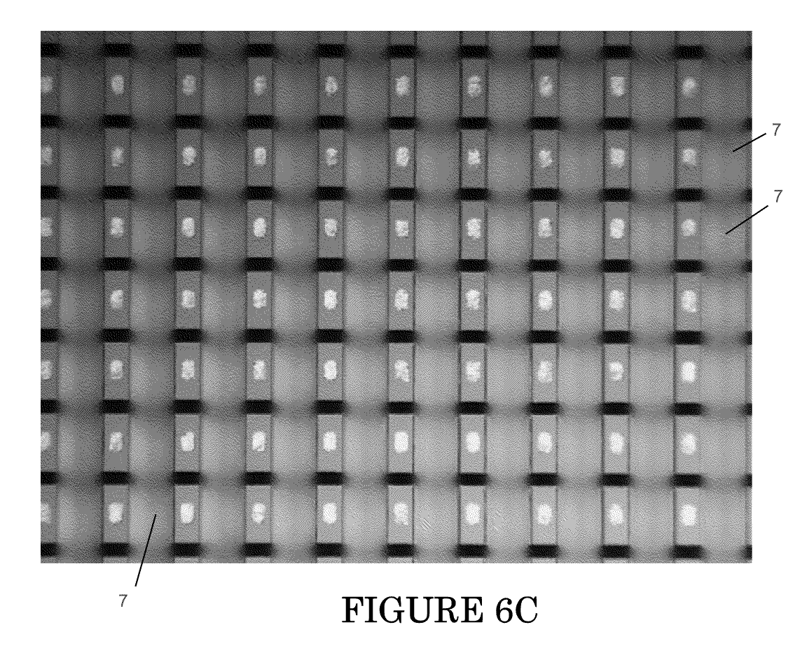

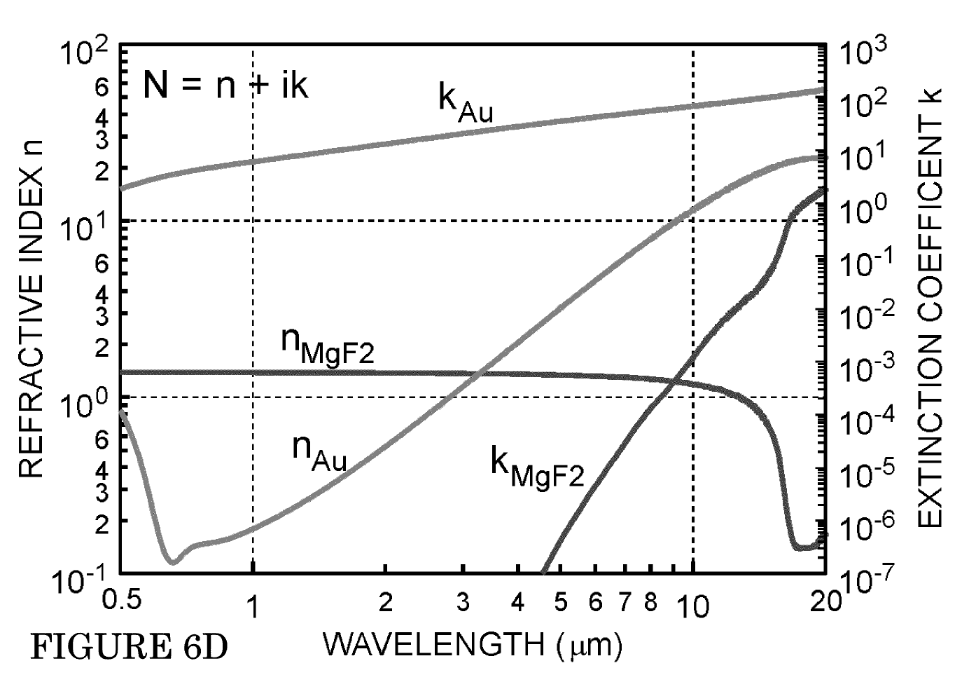

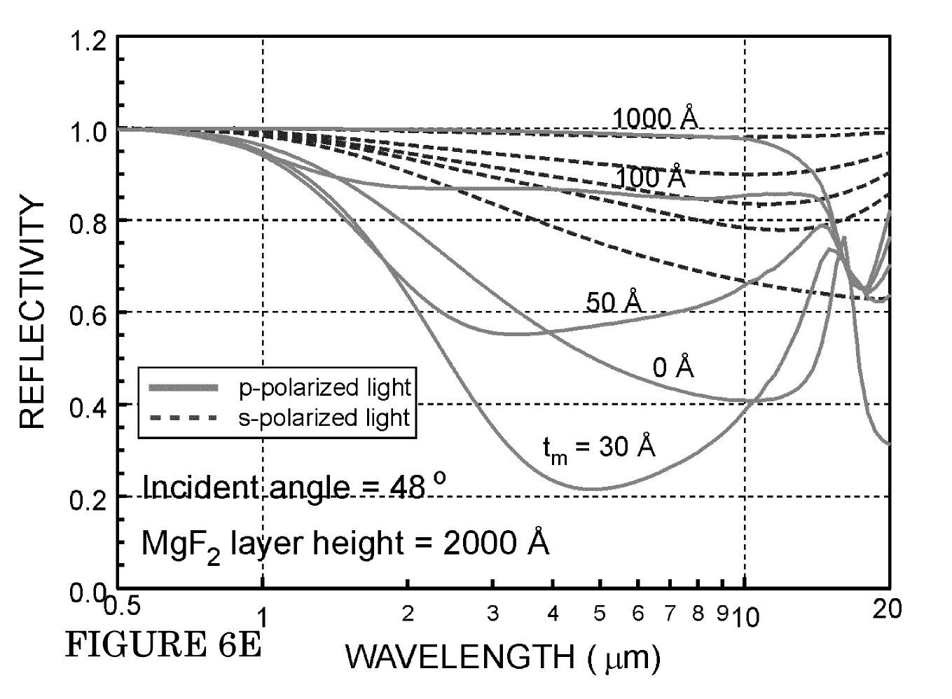

To ensure that the sidewall retains its high reflectivity R with the cover layer, R is calculated as a function of the gold layer vertical height tₘ and MgF₂ layer height t_{d}. The calculation is based on the transfer matrix formalism applied to optical thin films having wavelength-dependent complex refractive indices N. In the incident layer, which is GaAs, N=3.24+0i. The transmitted layer is assumed to be an epoxy layer whose N is 1.5+i. For Au and MgF₂, their N's are shown in FIG. 6D. The anomalous dispersion in n_{Au} near the wavelength λ=0.54 μm is due to plasmon excitation, whereas that in n_{MgF2} near 16.3 μm is due to optical phonon creation.

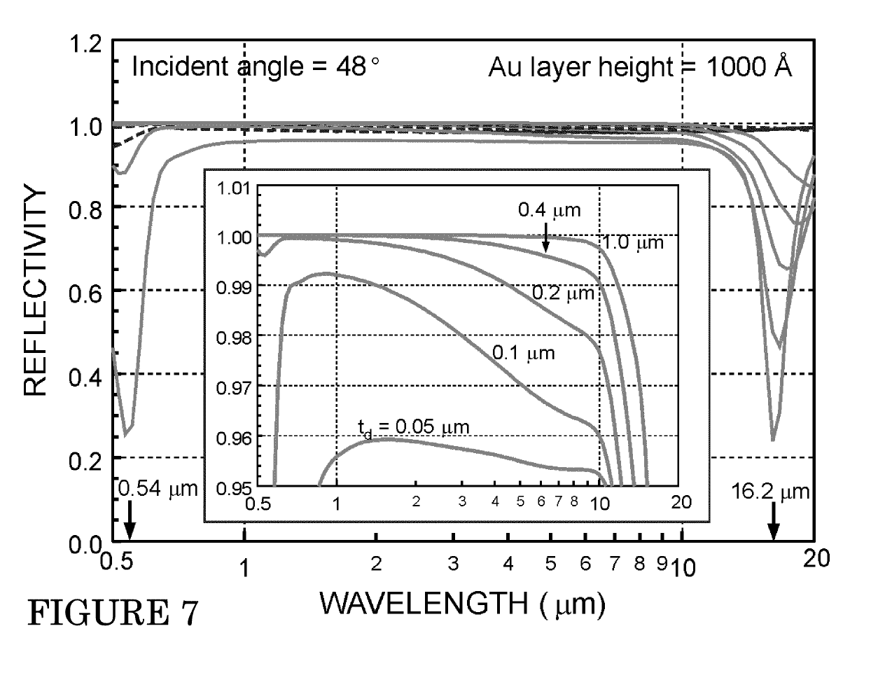

The thickness of the gold layer may be as thin as 30 Å and may be as thick as 0.1 micron or more. Increasing the thickness of the layer beyond 0.1 micron provides no noticeable effect. Preferably, the gold layer has a thickness in the range of 500 Å to 1000 Å. When the gold layer is thin, R of the p-polarized light in FIG. 6E can be as low as 20%. A substantial amount of light in this case tunnels through the MgF₂/Au layer and into the epoxy layer despite the incident angle is still larger than the critical angle. The small R is a case for the frustrated internal reflection. On the other hand, when the dielectric thickness is small, R in FIG. 7 reaches a minimum at λ=0.54 μm due to the excitation of surface plasmon polaritons on the gold surfaces and is the case for the attenuated internal reflection. Between 0.7<λ<15 μm, a small portion of the reflection is lost to ohmic heating in the metal. When λ is near 16.2 μm, surface phonon polariton absorption along the dielectric/gold interface is responsible for the R minimum. This surface effect is evident from the increased absorption at a small dielectric thickness in FIG. 7.

FIG. 6E shows the calculated sidewall retlectivity R for different Au thicknesses. The p-polarized light is responsible for QWIP absorption. The s⁻ polarized light is not coupled under the present corrugated coupling. From FIG. 6E, a gold layer with thickness ˜1000 Angstroms is shown to be required to produce good optical isolation. On the other hand, with such a thick layer of gold, R is not sensitive to the dielectric thickness. The inset of FIG. 7 shows R is generally larger than 0.95 for any t_{d}, and when t_{d}=1 μm, R becomes effectively unity within a wide wavelength range. Total internal retlection is thus restored in this thickness regime. In FPA implementation, a cover layer with tₘ=1000 Å and t_{d}=2000 Å will provide sufficient optical isolation with retlectivity >0.98 below λ=10 μm. This layer structure has been adopted in C-QWIP FPA production and the experimental R matches the theoretical value in this calculation.

In accordance with the present invention, one-corrugation-per-pixel geometry may be adopted to increase the active detector volume and incorporate a composite cover layer to preserve the large sidewall reflectivity, which results in a large detector quantum efficiency. Also, the detector material structure may be optimized such as the final state energy, the doping density, and the number of quantum well periods to improve the FPA operation under the existing readout electronics. As a result, high FPA sensitivity has been achieved, having characteristics in agreement with the detector model. Based on this model, a systematic analysis on the FPA performance was performed with a wide range of detector and system parameters. C-QWIP FPAs are capable of high speed imaging especially for those with longer cutoff wavelengths.

A preferred embodiment of the present invention achieves high definition focal plane arrays (FPAs) incorporating a one-corrugation-per-pixel geometry resulting in an increased performance single corrugation C-QWIP. The light coupling of C-QWIPs may rely on total internal reflection. In conventional FPAs, however, these sidewalls are often covered with various materials such as polyimide or epoxy backfill material for passivation or readout hybridization purposes. The optical properties of these materials can affect the sidewall reflectivity and change the detector performance. The quantum efficiency of a C-QWIP increases with the detector volume. But a thick active layer will also require a large operating voltage and has a small photoconductive gain, which may not be compatible with the existing readout electronics. In optimizing FPA performance, the readout electronic characteristics have to be taken into account. In accordance with the present invention, the C-QWIP structure for FPA applications has been optimized and successfully demonstrated a number of high sensitivity, large format FPAs. Using the principles of the present invention, detector optimization is achieved using a systematic analysis to identify the optimum structure for high speed infrared imaging.

With respect to the detector material design, in QWIP material structures, the locations of the (odd parity) final state energies Eₙ relative to the barrier height H play an important role in determining the detector characteristics such as the spectral bandwidth and dark current level. The absorption peak energy relative to barrier height H roughly divides the detectors into bound-to-bound, bound-to-quasi-bound, and bound-to-continuum detectors. To determine the energy structure of a QWIP accurately, the transfer-matrix formulism was employed. See K. K. Choi, S. V. Bandara, S. D. Gunapala, W. K. Liu, and J. M. Fastenau, “Detection Wavelength of InGaAs/AlGaAs quantum wells and superlattices,” J. Appl. Phys., vol. 91, 551-564 (2002). A QWIP usually contains a number of In_{y}Ga_{1-y}As wells and AlₓGa₁₋ₓAs barriers. InGaAs wells are adopted to reduce the intervalley scattering in the AlGaAs barriers for a larger photoconductive gain. The InGaAs well includes ˜5 Å of GaAs on each side to yield a better interface. The typical band diagram is shown in FIG. 6A. The wells and the contacts are doped with silicon to yield a finite Fermi Energy EF.

FIG. 6A is a typical energy diagram of a n-type QWIP along the growth (z) axis. In this figure, the wells are made of GaAs/InGaAs/GaAs layers. E₃ to E₆ are the resonant QW states. The shaded region above the barriers is the global conduction band.

The band structure of a QWIP is generally described in terms of minibands and the associated Bloch wavefunctions. However, when the barrier thickness B is large, the miniband width is small and the number of minibands that participate in optical absorptions is large. The overall absorption spectrum is determined by the variation of the oscillator strength among different minibands rather than the variation within each miniband. Moreover, when the miniband width is smaller than the individual level broadening, Bloch wavefunctions are not coherent in different parts of the material. In this case, each QW can be regarded as an isolated structure and one can use the single quantum well (SQW) Eigen functions ψₙ and Eigen values Eₙ to calculate its optical properties. The energy Eₙ depends on three structural parameters: H, barrier thickness B and the well width W. However, the optical absorption of a SQW is mainly a property of the well, i.e. its W and H, but not B. Therefore, the value of B can be chosen arbitrarily without affecting the detector optical properties.

To calculate the optical absorption of a QWIP, one can start with the Fermi Golden rule on the optical transition rate rₙ from E₁ to one of the final states Eₙ:

$$\begin{matrix}{r}_{n} ( ℏω ) = \frac{2 π}{ℏ} \int {\vert 〈 {ψ}_{n} , N - 1 \vert \frac{e}{{m}^{*}} A \cdot P \vert {ψ}_{1} , N 〉 \vert}^{2} \times {ρ}_{n} ( E ) δ ( E - ℏω - {E}_{1} ) d E \\ = \frac{{πe}^{2} N {ℏ}^{2}}{{m}^{* 2} {ɛ}_{r} {ɛ}_{0} V {\overline{ω}}_{n}} {\vert 〈 {ψ}_{n} \vert \frac{\partial }{\partial z} \vert {ψ}_{1} 〉 \vert}^{2} {ρ}_{n} ( ℏω + {E}_{1} )\end{matrix} \qquad ( 1 )$$

In equation (1) above, N is the number of photons with energy h̅ω within an active volume V. The ratio e/m* is the electron charge to the effective mass, εᵣ is the relative permittivity of GaAs, and A and P are the vector potential operator and momentum operator, respectively. ρ(E) is the energy distribution of Eₙ as a result of material nonuniformity. It is given by

$${ρ}_{n} ( E ) = \frac{1}{\sqrt{2 π} {σ}_{n}} exp ( - \frac{{( E - {E}_{n} )}^{2}}{2 {σ}_{n}^{2}} ) \qquad ( 2 )$$

where σₙ is the standard deviation of the line broadening. In the prefactor of the last step of (1), we have replaced ω by the average ω̅ₙ=(Eₙ-E₁)/ h̅ for the Eₙ transition. Polarized light can be assumed as incident at the side of the sample so that it travels parallel to the material layers with its polarization pointing along the growth direction, z. If the light is incident normally onto the QW layers, there will be no infrared absorption under the present formulism.

To proceed, we note that N/V=√εᵣIₛ/(c h̅ω), where Iₛ is the incident intensity in W/cm², and c is the speed of light in vacuum. With the oscillator strength fₙ defined by

$$\begin{matrix}{f}_{n} = \frac{2 ℏ}{m * {\overline{ω}}_{n}} {\vert 〈 {ψ}_{n} \vert \frac{\partial }{\partial z} \vert {ψ}_{1} 〉 \vert}^{2} & ( 3 ) \\ {r}_{n} ( ℏω ) = \frac{π {e}^{2} {I}_{s}}{2 m * \sqrt{{ɛ}_{r}} {ɛ}_{0} c ω} {f}_{n} {ρ}_{n} ( ℏω + {E}_{1} ) & ( 4 )\end{matrix}$$

The total transition rate to all n final states is

$$r ( ℏω ) = {\sum }_{n = 2}^{∞} {r}_{n} ( ℏω ) = \frac{π {e}^{2} {I}_{S}}{2 m * \sqrt{{ɛ}_{r}} {ɛ}_{0} c ω} {\sum }_{n = 2}^{∞} {f}_{n} {ρ}_{n} ( ℏω + {E}_{1} ) \qquad ( 5 )$$

The number of transitions per unit volume G( h̅ω) is (Nₛ/L)r( h̅ω), where Nₛ is the two-dimensional electron density in each QW, and L=W+B is the total thickness of each QW period. The optical transitions lead to an exponential decay of Iₛ so that G( h̅ω) is also equal to

$$G = - \frac{1}{ℏω} \frac{d}{d x} [ {I}_{0} exp ( - α x ) ] = \frac{α}{ℏω} {I}_{S} \qquad ( 6 )$$

where α is the absorption coefficient of the z-polarized light. Equating G leads to

$$α ( λ ) = \frac{{N}_{D} W}{L} \frac{{πe}^{2} ℏ}{2 m * \sqrt{{ɛ}_{r}} {ɛ}_{0} c} {\sum }_{n = 2}^{∞} {f}_{n} {ρ}_{n} ( λ ) \qquad ( 7 )$$

where N_{D} is the volume doping density in the well.

The fact that the α lineshape is independent of barrier thickness B can be understood from (3), where fₙ is related to the overlap integral of ψₙ and an (unnormalized) wavefunction ψₚ≡∂ψ₁/∂z. One can interpret this ψₚ as the actual final state wavefunction transformed from ψ₁ after an optical interaction. Since ψₚ is not an energy eigenstate of the SQW structure, its spectral weight A(E) spreads across a range of E. For a given pair of W and H values, ψₚ, A(E), and f(E) are all fixed. Different ψₙ's for different B are to sample these fixed quantities at different energies. The absorption spectrum thus is not affected by barrier thickness B.

As an example, FIG. 6B is the calculated fₙρₙ(λ) of a typical QWIP whose QW is made of 500 Å Al_{0.19}Ga_{0.81}As/ 7 Å GaAs/ 35 Å In_{0.1}Ga_{0.9}As/7 Å GaAs/500 Å Al_{0.19}Ga_{0.81}As. The wavefunctions ψₙ's in equation (3) are obtained by solving the Schrödinger equation numerically (see, K. K. Choi, et al, “Detection Wavelength of InGaAs/AlGaAs quantum wells and superlattices,” J. Appl. Phys., vol. 91, 551-564. 2002). After f(λ)≡Σfₙρₙ(λ) is known, the material α in equation (7) can be calculated for a given N_{D}. For N_{D}=1×10¹⁸ cm⁻³, the peak α is about 0.15 μm⁻¹ as shown in FIG. 6B. FIG. 6B also shows the location of λ_{H}, which divides the transitions above and below H. In general, the majority of the transitions should be above H for a large photocurrent but yet, H should not be lower than the half maximum of the absorption lest it will free more thermally excited electrons than photoelectrons.

In FIG. 6B, the dashed curves show the individual fₙρₙ(λ) assuming σₙ=n+4 meV. The solid curve shows the combined oscillator strength f(λ). The blue line shows the wavelength λ_{H} that divides the bound-to-bound and bound-to-continuum transitions. The right y-axis shows the corresponding absorption coefficient for N_{D} of 1×10¹⁸ cm⁻³.

As to the detector structure design, since the material α is for z polarization light only, an enabling light coupling scheme is needed under normal incident condition. For the present corrugated coupling, the detector structure in the form of one-corrugation-per-pixel design is shown in FIG. 5. The detector consists of an active material with thickness tₐ, a top contact layer t_{c}, and a bottom contact layer t_{b}. The total thickness (or height as shown in FIG. 5) is calculated as t=tₐ+t_{b}+t_{c}. Underneath the structure, there is a common contact layer connecting all the detectors. The corrugation period p is designed to be the same as the pixel pitch. Among the four pixel sidewalls, two are inclined at approximately 45° and the other two are substantially more vertical. The 45° sidewalls are covered with a dielectric/metal layer. With this detector architecture, the processed pixels in an array are shown in FIG. 6C, which is a top view of C-QWIP pixels in an array. Shown in gold are the metal reflecting layers 7.

In operation, the QWIP detector element receives incident radiation through a substantially-transparent substrate. Side surfaces of the C-QWIP detector element reflect the incident radiation, thereby redirecting the radiation. The reflected radiation is directed through the active detector material irrespective to its wavelength. Thus, the sloped sides may be seen as a broadband light coupling scheme.

Initially, as reported in C. J. Chen, K. K. Choi, M. Z. Tidrow, and D. C. Tsui, “Corrugated quantum well infrared photodetectors for normal incident light coupling,” Appl. Phys. Lett., vol. 69, pp. 1446-1448, (1996), C-QWIPs were designed to rely on total internal reflection of light at the angled sidewalls. However, it was later discovered that the detector η was greatly affected by the materials that came in contact with the sidewalls, as reported in K. K. Choi, K. M. Leung, T. Tamir, and C. Monroy, “Light coupling characteristics of corrugated quantum well infrared photodetectors,” IEEE J. of Quan. Electr., vol. 40, pp. 130-142 (2004) and N. C. Das and K. K. Choi, “Enhanced corrugated QWIP performance using dielectric coverage,” IEEE Trans. Elect. Dev., vol. 47, No. 3, pp. 653-655 (2000).

In accordance with a preferred embodiment of the present invention, a composite cover layer is used for sidewall encapsulation. A preferred embodiment composite film consists of a layer of magnesium fluoride (MgF₂) for electrical isolation and a layer of gold (Au) for optical reflection. The protective layer of composite material provides optical insulation against the surrounding material and maintains a large sidewall reflectivity. The composite material is substantially inert so that it will not short out the detectors. The dielectric film MgF₂ is chosen for its high dielectric strength (breakdown voltage=16 V for a 1000 Å thick film), low conducting current (=1×10⁻⁸ A/cm² at 6 V direct bias for a 4400 Å thick film), low refractive index, and small extinction coefficient in the infrared. However, magnesium fluoride (MgF₂) and gold (Au) are merely an exemplary materials, and any materials with similar characteristics can be used. Examples are zinc sulfide, zinc selenide, calcium fluoride, barium fluoride, silicon nitride and silicon dioxide for the dielectric layer, and silver and chromium for the metal layer.

To ensure that the sidewall retains its high reflectivity R, R is calculated as a function of the Au layer vertical height tₘ and MgF₂ layer height t_{d}. The calculation is based on the transfer matrix formalism applied to optical thin films having wavelength-dependent complex refractive indices N (see for example, G. R. Fowles, Introduction to Modern Optics, New York: Dover, 1975, pp. 97-98). In the incident layer, which is GaAs, N =3.24+0i, the transmitted layer is assumed to be an epoxy layer whose N is 1.5+1i. For Au and MgF₂, their N's are shown in FIG. 6D. FIG. 6D shows the complex refractive indices, N=n+ik, of MgF₂ and Au films as a function of wavelength. The anomalous dispersion in n_{Au} near 0.54 μm is due to plasmon excitation, whereas that in n_{MgF2} near 16.3 μm is due to optical phonon creation.

When the gold (Au) layer is thin, R of p-polarized light in FIG. 6E, which is responsible for QWIP absorption, can be as low as ˜20%. A substantial amount of light in this case tunnels through the MgF₂/Au layer and into the epoxy layer despite the incident angle being larger than the critical angle. The small R is due to internal reflection. On the other hand, when the dielectric thickness is small, reflectivity R in FIG. 7 reaches a minimum at λ=0.54 μm due to the excitation of surface plasmon polaritons on the gold surfaces and is a case of the attenuated internal reflection. Between 0.7<λ<15 μm, a small portion of the reflection is lost to ohmic heating in the metal. When λ is near 16.2 μm, surface phonon polariton absorption along the MgF₂/Au interface is responsible for the reflectivity R minimum. This surface effect is evident from the fact that the absorption increases with decreasing MgF₂ thickness in FIG. 7.

FIG. 6E graphically illustrates the calculated sidewall reflectivity R for different Au thicknesses. The p-polarized light is responsible for QWIP absorption. The s-polarized light is not coupled under the present corrugated coupling. From FIG. 6E, a gold (Au) layer with thickness of approximately 1000 Å is shown to be adequate in providing good optical isolation. With a thick layer of Au, R is not sensitive to the MgF₂ thickness. The inset of FIG. 7 shows R is generally larger than 0.95 for any t_{d}, and when t_{d}=1 μm, R becomes effectively unity within a wide wavelength range. Total internal reflection is thus restored in this thickness regime. In FPA implementation, a cover layer with tₘ=1000 Å and t_{d}=2000 Å will provide sufficient optical isolation with R>0.98 below λ=10 μm. This layer structure has been adopted in C-QWIP FPA production with the finding that the experimental R results substantially match the theoretical calculated value.

Illustrated in FIG. 7 is the calculated sidewall reflectivity R for different MgF₂ thicknesses. The inset shows reflectivity R in an expanded scale.

Assuming total internal reflection, η of a C-QWIP that is completely filled with active material is given by

$$η ( {t}_{a} = t ) ≡ {η}_{0} = \frac{1}{p} [ t + \frac{{e}^{- α p}}{2 α} ( 1 - {e}^{2 α t} ) ] . \qquad ( 8 )$$

Equation (8) is obtained from a geometric-optical model under unpolarized light illumination with 100% substrate optical transmission. For a pixel with p=25 μm and t=11 μm, the η spectrum having the material α in FIG. 6B is plotted in FIG. 7. The peak η is 35.4%, which agrees with EM field modeling as reported in Choi, et al. “Light coupling characteristics of corrugated quantum well infrared photodetectors,” IEEE J. of Quan. Electr., vol. 40, pp. 130-142 (2004). Note that the η spectrum has a slightly different lineshape than the α spectrum. Due to the long optical pathlength of a C-QWIP pixel, the amount of light absorbed can be substantial even when α is small. The absorption spectrum is thus broader than the α spectrum.

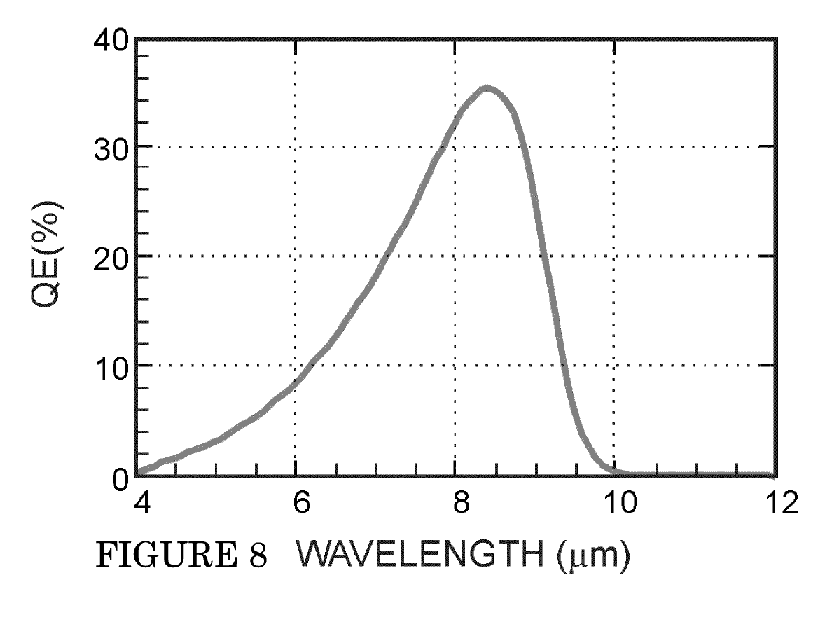

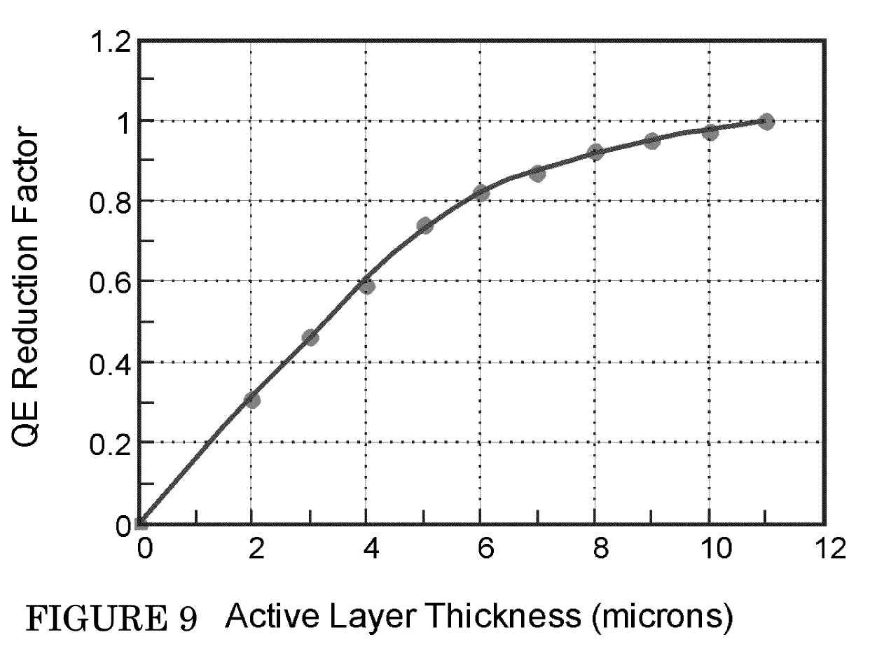

FIG. 8 illustrates the calculated η(λ) of a C-QWIP having α shown in FIG. 6B. In detector material optimization, the readout integrated circuits (ROICs) need to be taken into account. Due to the limited bias range of a typical ROIC, feasibility of the adoption of a very thick active layer is limited. To maintain the detector geometry, one can increase the contact thicknesses t_{b} and t_{c}. The resulting η will be smaller and can be characterized by a η reduction factor κ(tₐ) such that η(tₐ)=κ(tₐ)η₀, where η₀ is from equation (8), and κ(tₐ) is obtained from EM field modeling. When the QWIP material is placed near the middle of the corrugation where t_{b}=t_{c}=(t−tₐ)/2, κ is maximized for a given tₐ, and its value is shown in FIG. 9. FIG. 9 shows the η reduction factor κ as a function of tₐ. The circles are from EM field simulation, and the curve is a fit to this simulation. For a given tₐ<11 μm, η(tₐ)=κη₀. From FIG. 9, it is seen that the reduction of κ is nonlinear as tₐ is reduced from 11 μm. For example, when tₐ is reduced to 6 μm, η retains 80% of its original value.

Experimental results for the FPA quantum efficiency and conversion efficiency follow. Equipped with the above detector model, this model was tested with different material structures and pixel pitches. To determine η of an FPA experimentally, a test detector (TD), which is from the same wafer material as the FPA, is processed into an edge coupled detector. The material spectral responsivity R(V, λ) is measured from this detector at each substrate voltage V. η_{TD} is related to R(V, λ) by

$${η}_{TD} ( V , λ ) ≡ \frac{hc}{eg ( V )} \frac{R ( V , λ )}{λ} \qquad ( 9 )$$

where h is the Plank constant and g(V) is the photoconductive gain. Since C-QWIP structures preserve the spectral lineshape of the material as reported in Chen, et al. “Corrugated quantum well infrared photodetectors for normal incident light coupling,” Appl. Phys. Lett., vol. 69, pp. 1446-1448 (1996), the FPA η(V, λ) will be assumed to be the same in shape as the η_{TD} spectrum. The normalized η spectrum S(V, λ) can thus be obtained from R(V, λ)/λ, and η(V, λ) can be expressed as η(V)S(V, λ), where η(V) is the peak FPA quantum efficiency. The value of η is a function of V because the photoelectrons have to transmit out of the QW before they can become photocurrent. This field ionization process depends on V.

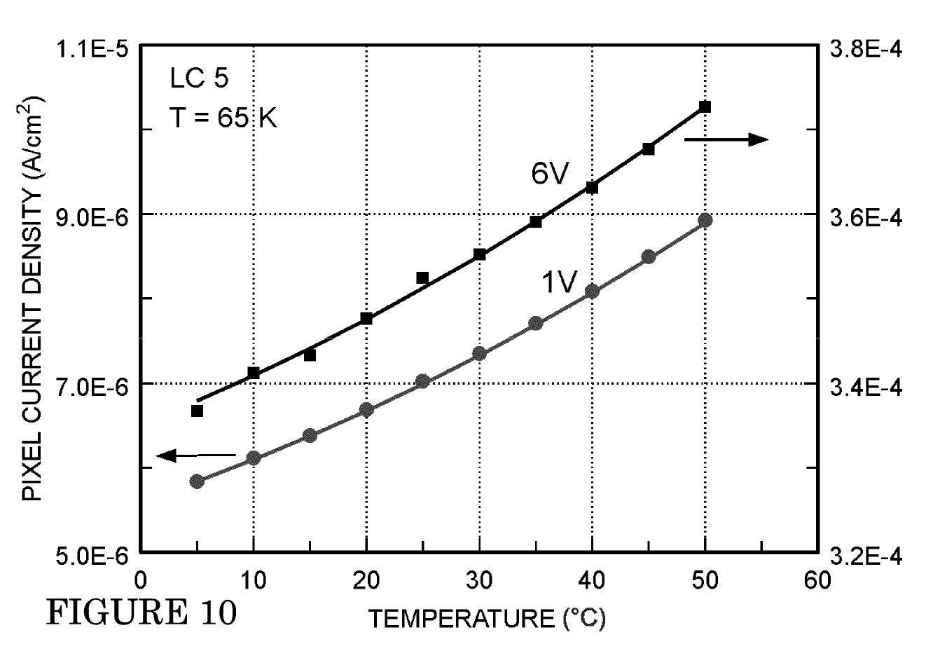

Next, the FPA pixel current as a function of V is measured at a constant detector temperature T. The FPA is placed in front of a blackbody source through an optical window. At each blackbody temperature T_{B}, the pixel I-V characteristics are measured. To extract the FPA conversion efficiency [CE(V≡η(V)g(V)], we fit J(V, T_{B}) to

$$\begin{matrix}J ( V , {T}_{B} ) = {J}_{d} ( V ) + {J}_{p} ( V , {T}_{B} ) \\ = {J}_{d} ( V ) + \frac{π e}{4 {F}^{2} + 1} \cdot C E ( V ) \cdot {\int }_{{λ}_{1}}^{{λ}_{2}} S ( V , λ ) L ( {T}_{B} , λ ) d λ ,\end{matrix} \qquad ( 10 )$$

where J is the total current density, J_{d} is the dark current density, and Jₚ is the photocurrent density. λ₁ and λ₂ are the lower and upper bounds of the measurement encompassing the detector absorption spectrum, F=2.2 is the f-number of the dewar, and L(T_{B}, λ) is the photon spectral radiance. At each V, the two fitting parameters to J(V, T_{B}) are J_{d}(V) and CE(V). FIG. 10 shows the typical fitting to the data. FIG. 10 graphically illustrates the pixel current density (symbols) at each V is plotted against T_{B}. The solid curves are fittings to the data using J_{d} and CE as fitting parameters. Finally, to determine η(V) from CE(V), the value of g(V) is obtained from measuring the generation-recombination noise of the test detector at 77 K based on iₙ²=4egI_{d}Δf, where iₙ is the noise current, I_{d} is the dc dark current and Δf is the noise bandwidth

In the following, experimental results from four focal plane arrays (FPAs) are disclosed. These FPAs have different cutoff wavelength λ_{c}, N_{D}, tₐ and p. By varying these parameters, one can assess the general properties of a C-QWIP FPA and the validity of the detector model. The labeling of these FPAs is based on an internal tracking scheme. Most of the FPAs are AR-coated. By comparing those with and without AR-coatings, we found that AR-coating generally improves the photoresponse by 28%, which indicates the substrate transmission to be at 90% with coating. Therefore, for those FPAs that are not AR-coated, their η is multiplied by 1.28 to account for the substrate reflection loss.

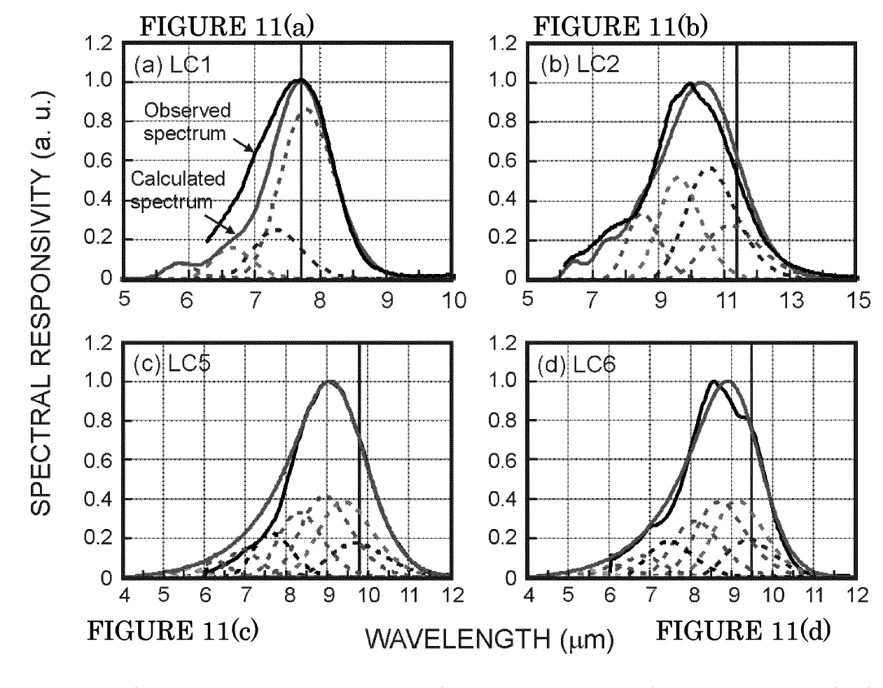

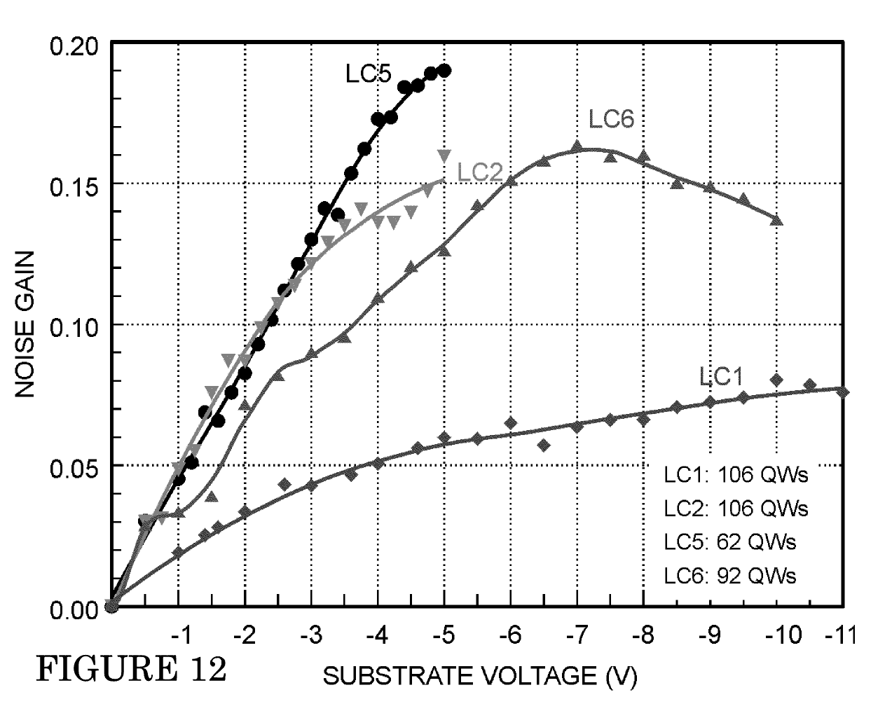

The first focal plane array FPA is known as LC1. The quantum well is made of AlₓGa₁ₓAs/GaAs/In_{y}Ga_{1-y}As/GaAs/AlₓGa₁₋ₓAs, where x=0.21, y=0.1, B=700 Å, and W=5+40+5 Å. The doping is at 0.9N₀, where N₀≡1×10¹⁸ cm⁻³. The calculated spectral lineshape is shown in FIG. 11(a). At the peak, α is 0.0864 μm⁻¹ and η₀ is 28.8%. The structure contains 106 QW periods, giving tₐ=7.95 μm and κ=0.924. The resulting η is therefore 26.6%. The gain curve g(V) is shown in FIG. 12. With the blackbody optical measurement, the experimental η can be deduced. At −3V, η is 7.1%.

FIG. 11 shows the calculated responsivity for each individual state, their combined spectrum, and the measured spectrum. The straight line divides the transitions below and above the barrier height. To assess η at higher V, which is beyond the present ROIC operating range, another FPA was adopted with a fan-out board, with which the pixel characteristics can be measured by external circuits. The measured CE is 2.84% at −11V. With g=0.077 at the same V, the observed η is 36.9%. This measured value is higher than the predicted value, and the discrepancy can be due to the uncertainty in the doping density. Meanwhile, a large V is needed in this FPA partly because of the large number of QW periods and partly because of the bound-to-bound nature of the dominant transition in this detector as seen in FIG. 11(a). Although a large V is required for this FPA, a QE above 30% is nevertheless observed under this light coupling scheme. To utilize a strictly bound-to-quasi-bound (BQ) detector in which the absorption peak coincides with H, a high voltage ROIC is needed.

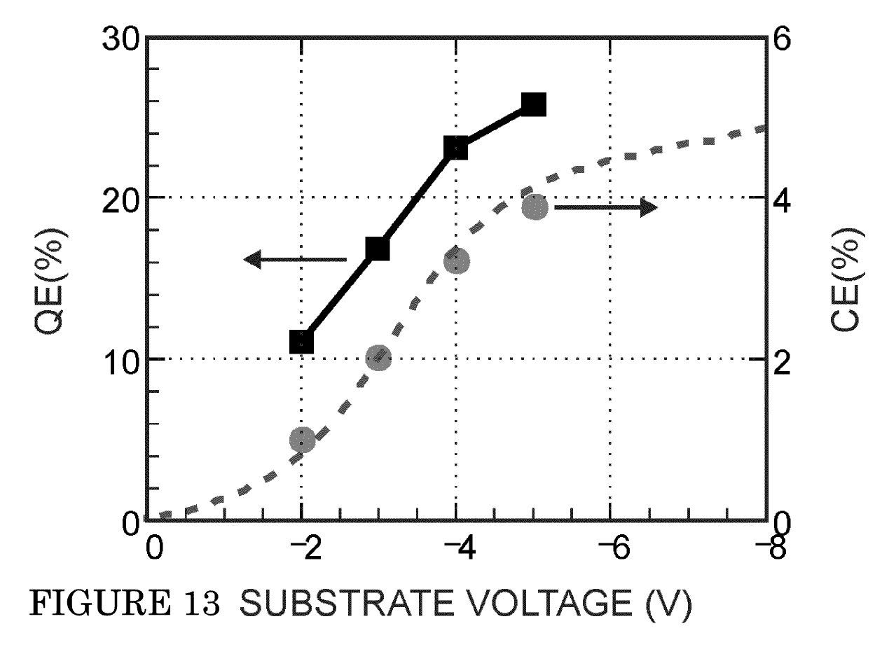

The second focal plane array FPA, LC2, uses a bound-to-continuum (BC) structural design, in which λ_{H}≈λ_{c}. It has the same structure as LC1 except that x=0.12. The calculated and the observed spectra are shown in FIG. 11(b). The αₚₑₐₖ is calculated to be 0.0593 μm⁻¹. This value is smaller than that of LC1 because of the wider spectral width of a BC detector. The integrated oscillator strength however remains the same. The theoretical η is thus smaller at 22.8%. FIG. 12 graphically illustrates the measured gain of the detectors at 77 K. The measured g in FIG. 12 reaches 0.15 at −5V, which is nearly twice that of LC1. The larger g is due to the smaller intervalley scattering in the smaller x detectors and a larger photoelectron energy relative to the barrier height in a BC detector. The measured CE as a function of V is shown in FIG. 13. With CE of 3.90% at −5V, the deduced η is 25.8%. This value of η is close to the calculated value. Therefore, by employing a BC structure, the photoelectrons can be fully ionized at a lower voltage, and it can be reached by the present ROICs. In FIG. 13, the background photocurrent I_{bp} of the test detector is plotted, scaled by a constant factor to match the FPA CE data. FIG. 13 shows the LC2 FPA η (squares) and CE (circles) as a function of V. The dashed curve shows the background photocurrent of a single test detector in arbitrary units. Since I_{bp} is directly proportional to ηg, I_{bp} and CE should share the same voltage dependence. The similar functional form of the two supports the FPA measurements. It also indicates a larger FPA CE at higher bias.

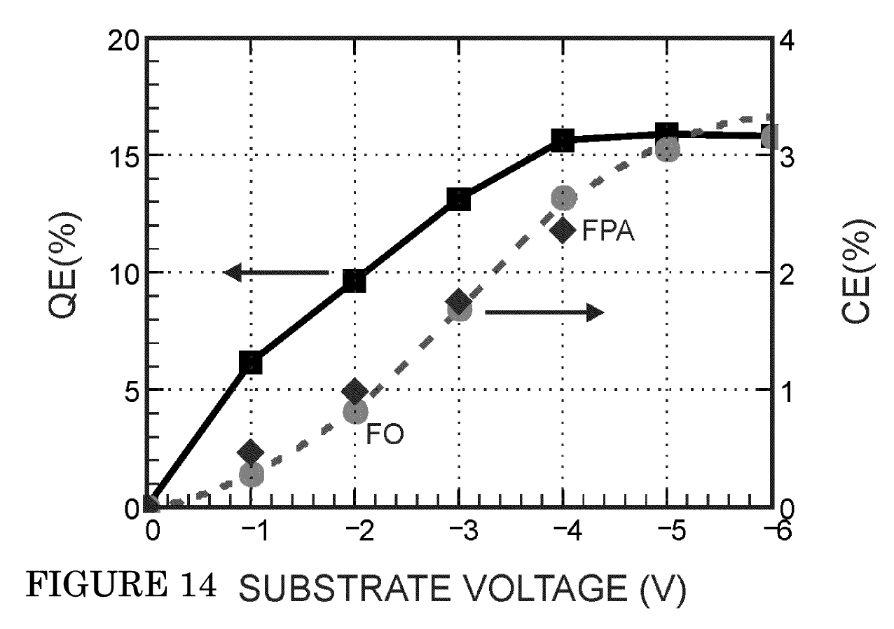

The third focal plane array FPA, LC5, uses a bound-to-quasi-bound-plus (BQ+) design, which is defined when λₚ<λ_{H}<λ_{c}. This structure has the characteristics between the BQ and BC detectors. It has a lower operating voltage than BQ detectors and a lower dark current than BC detectors. To reduce the operating voltage further, the number of QWs N_{w} is set at 62. The corresponding tₐ=4.658 μm and κ=0.686. Other material parameters are x=0.19, y=0.1, W=7+35+7 Å, B=700 Å, and N_{D}=N₀. The calculated and observed spectra are shown in FIG. 11(c). The calculated α is 0.0785 μm⁻¹ and η is 18.8%. The gain is 0.19 at −5V, which is higher than that of both LC1 and LC2, consistent with 1/N_{w} dependence. Scaled to 106 QWs, g=0.11, which is between the 0.077 for LC1 and 0.15 for LC2. This ordering of g is also expected from the types of detectors. The experimental CE is shown in FIG. 14. FIG. 14 shows the LC5 CE for the fan-out (circles) and the FPA (diamonds). The dashed curve shows the background photocurrent of a test detector in arbitrary unit. The figure also shows η of the fan-out (squares). The values of CE and η are 3.05% and 16.1%, respectively, at −5V. The measured η is slightly below the predicted value of 18.8%. But if we account for the 10% substrate reflection even with AR-coating, the theory and experiment are in good agreement.

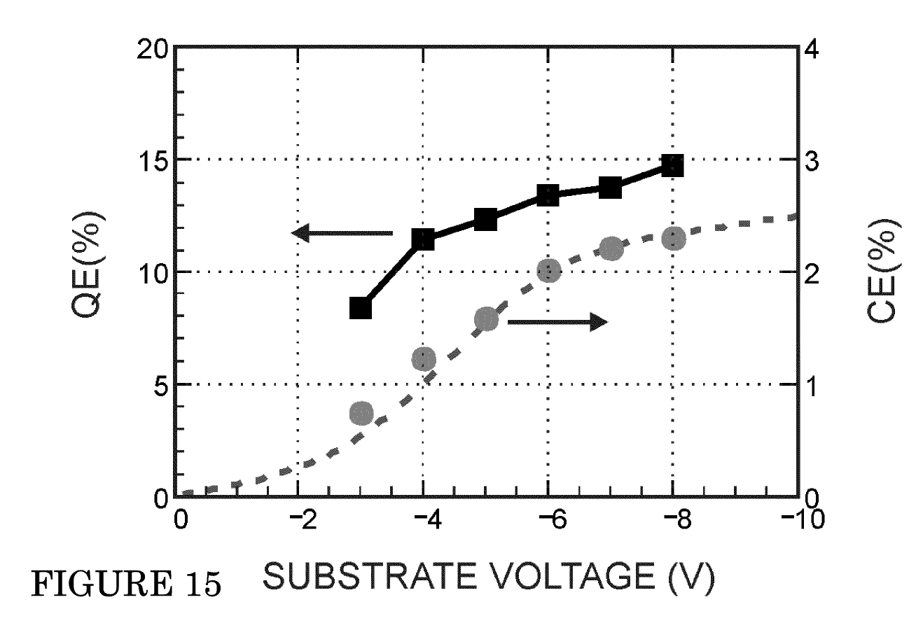

The fourth focal plane array FPA LC6, has the same basic QW structure as LC5 except that N_{D} is 0.5N₀ and N_{w} is 92. The pixel pitch p is 20 μm instead of 25 μm. With a smaller corrugation, the detector has a large κ=0.985. Despite this large κ, the theoretical η is only 14.2% due a lower N_{D}. On the other hand, with a lower current level, the FPA can bias up to −8V, at which the measured CE is 2.3% and η is 14.7% as shown in FIG. 15. FIG. 15 shows LC6 FPA η (squares) and CE (circles). The dashed curve shows the background photocurrent of a test detector in arbitrary unit.

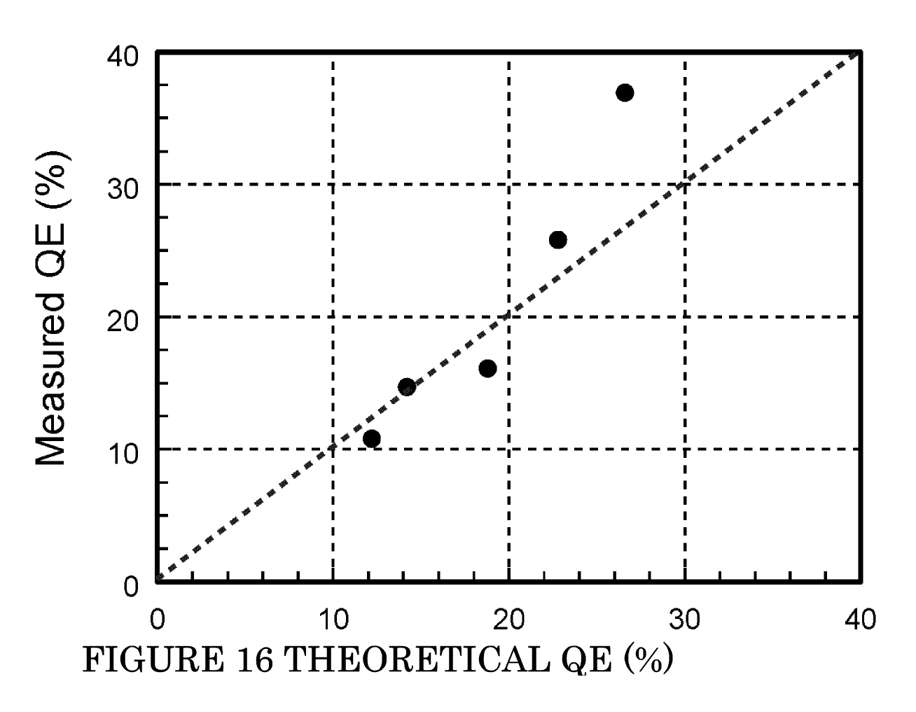

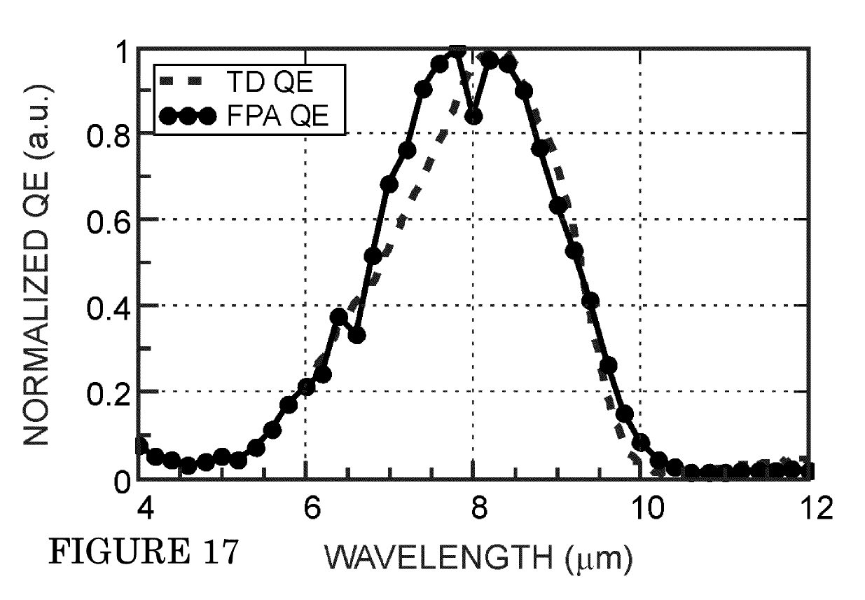

The above predicted and observed η are plotted in FIG. 16, along with an additional data point not described in this paper. In FIG. 16 the observed η (circles) are plotted against the predicted values. The dash line represents prefect agreement. Because of the different material and pixel structures, the predicted η spans from 12 to 27%. The observed η follows this prediction closely. In addition to these focal plane arrays (FPAs), other FPAs were also produced using similar material recipes. The deduced η's are also found to be consistent with the present model. The spectral response of one of these FPAs is shown in FIG. 17, which illustrates the η spectrum of the LC4 FPA (not described further herein) and the test detector at V=2V. They share similar lineshape between the focal plane array (FPA) and the test detector, which substantiates the assumption that C-QWIP structures preserve the material absorption spectrum.

Performance of the focal plane array (FPA) in terms of noise equivalent temperature difference (NEΔT) was evaluated adopting the following expression:

$$NE Δ T = {\frac{1}{C} [ ( \frac{2 {gN}_{tot} + {n}_{rd}^{2}}{{N}_{tot}^{2}} ) {( 1 + \frac{1}{r} )}^{2} + {u}^{2} ]}^{1 / 2} \qquad ( 11 )$$

where C is the thermal contrast, g is the detector noise gain, Nₜₒₜ is the total number of collected electrons, n_{rd} is the read noise, r is the photocurrent to dark current ratio at the operating temperature T, and u is the spatial nonuniformity. Since n_{rd} and u are not related to the detector design, they were set to zero in this section to assess the detector limited, temporal NEΔT.

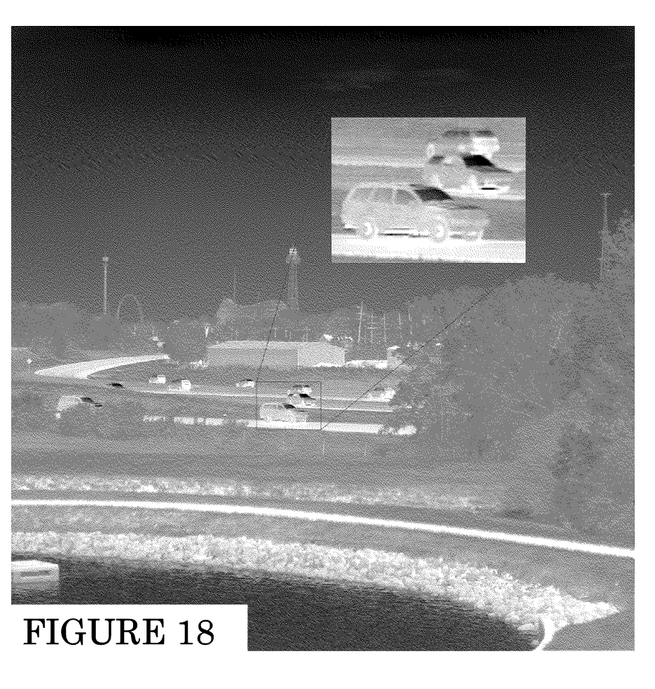

Table 1 lists the measured parameters for the four FPAs. The detector currents Jₚ and J_{d} are measured at the stated T, V, and T_{B}=27° C. with f/2.2. From the measured Jₚ and J_{d}, the values of Nₜₒₜ and r are known for a specific integration time τᵢₙₜ(=1 or 2 ms). Combined with the measured g, the detector limited, temporal NEΔT can be calculated for each FPA. The result is around 20 mK for all FPAs. In the actual camera operation, the NEΔT will also depend on other factors such as read noise and system noise. For example, the total temporal NEΔT of the LC5 FPA camera was measured to be 22 mK at 2 V, 4 ms and 55 K (as reported in Forrai, et al., “Characterization of a C-QWIP LWIR camera,” Proc. of SPIE, vol. 6543, pp. 654317 1-8 (2007). The longer τᵢₙₜ is needed to compensate for the lower operating voltage. FIG. 18 shows a typical infrared image taken by a 1024×1024 LC5 focal plane array (FPA).

Regarding system analysis, from Table 1, the LC1 FPA shows the best performance since it has the lowest NEΔT (16.1), the highest operating temperature (70 degrees K), and the lowest charge capacity requirement. Table 1 lists the measured FPA parameters and the calculated NEΔT. Γ is the FWHM of the QE spectrum.

| | | | | | | | | Jₚ | | | | | |
|---|---|---|---|---|---|---|---|---|---|---|---|---|---|
| | # | λ_{c} | η | CE | Γ | T | V | (27° C.) | J_{d} | τᵢₙₜ | Nₜₒₜ | | NEΔT |
| FPALC | QWs | μm | (%) | (%) | (μm) | (K) | (V) | (μA/cm²) | (μA/cm²) | ms | Me⁻ | gain | (mK) |
| 1 | 106 | 8.6 | 36.9 | 2.84 | 1.5 | 70 | −11 | 25.8 | 14.6 | 2 | 3.15 | 0.077 | 16.1 |
| 2 | 106 | 11.6 | 25.8 | 3.90 | 3.7 | 58 | −5 | 217 | 425 | 1 | 25.1 | 0.150 | 19.3 |
| 5 | 62 | 10.2 | 16.1 | 3.05 | 3.1 | 60 | −5 | 50.3 | 44.8 | 2 | 7.42 | 0.192 | 23.0 |
| 6 | 92 | 9.8 | 13.7 | 2.21 | 2.5 | 64 | −7 | 57.4 | 16.0 | 2 | 3.66 | 0.161 | 22.1 |

The calculated NEΔT did not include the read noise, which will play an important role when both g and Nₜₒₜ are small, which is the case for LC1. To investigate the impacts of extrinsic noises, the same detector model was applied to perform a general analysis on the FPA performance in the presence of n_{rd}. The n_{rd} was generalized to include all other temporal noises that are not related to the detector g-r noise, so that it can take on a large value. A full bias was assumed on the detectors, e.g. ˜80 mV/QW. Besides η, models for the gain and dark current were needed. Experimentally, in a larger set of detectors it was found that g₁=−54.68x+26.18 at full bias, where g₁ is the gain of a single QW, and x is the Al mole fraction of the barriers. For a structure with N_{w} QWs, the gain g will be g₁/N_{w}. The precise value of g is not required in the analysis since NEΔT does not depend on g when the detection is in background limited performance (BLIP) as reported in K. K. Choi, C. Monroy, V. Swaminathan, T. Tamir, M. Leung, J. Devitt, D. Forrai, and D. Endres, “Optimization of corrugated-QWIPs for large format, high quantum efficiency, and multi-color FPAs,” Proc. of SPIE, vol. 6206, pp. 62060B 1-15, (2006), hereby incorporated by reference. For dark current, the semi-empirical formula was used:

$${J}_{d} = {J}_{0} ( V ) {e}^{- {E}_{a} / kT} = {J}_{o} ( V ) exp ( - \frac{H - {E}_{1}}{kT} ) exp ( \frac{{E}_{F}}{kT} ) \qquad ( 12 )$$

where J₀(V) is a prefactor deduced from experiment, and Eₐ is the activation energy. Eₐ is a function of H, E₁, and E_{F} as stated in equation (12). Based on equation (12), after J₀(V) is known from a set of well calibrated samples, J_{d} for detectors with any λ_{c}, N_{D} and T can be estimated. The result is generally accurate to within a factor of two from the experimental value. In the present analysis, we use J₀=1.80×10⁴ A/cm² at 80 mV/QW.

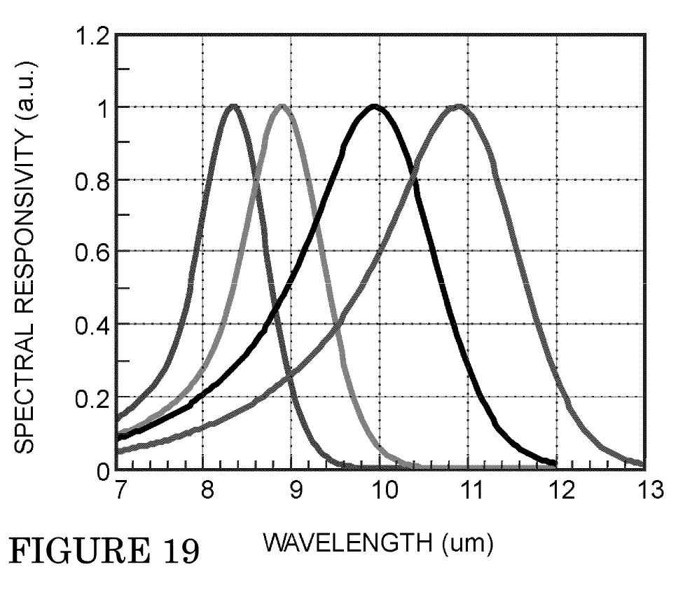

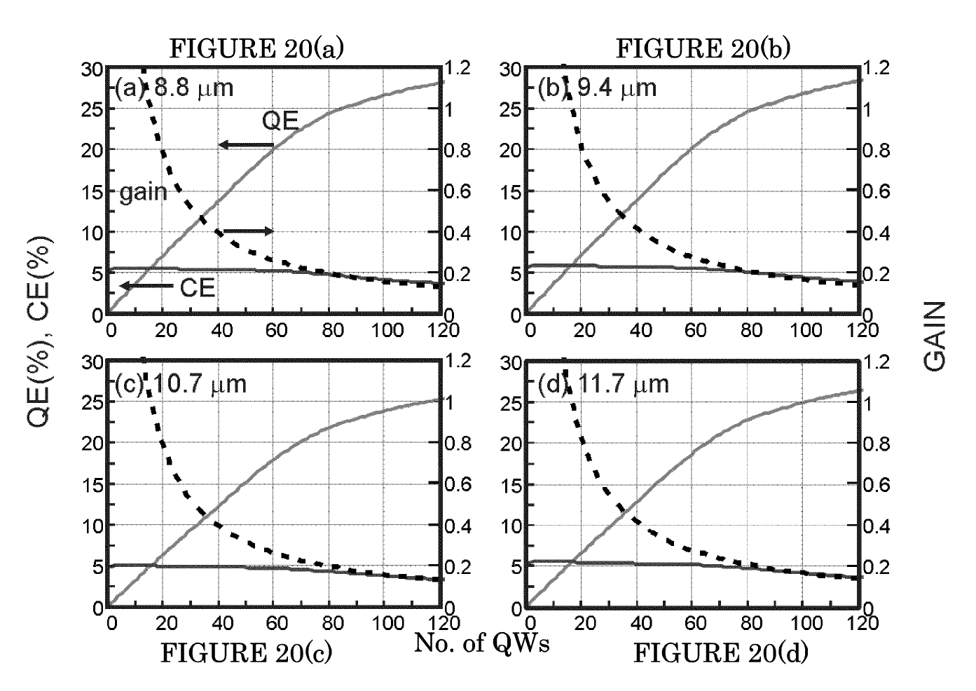

Four detector designs were considered; the material (x, y) values were (0.19, 0.1), (0.175, 0.1), (0.19, 0) and (0.175, 0), respectively. These detectors were tailored for high speed imaging. Therefore, a high doping density of 1×10¹⁸ cm⁻³ was assumed. With these detector parameters, the calculated spectral responsivity is shown in FIG. 19. FIG. 19 illustrates the normalized spectral responsivity of four detectors considered in the system analysis. The calculated η, g, and CE are shown in FIG. 20, assuming 25 μm pixel pitch, 90% substrate transmission, and 90% pixel fill factor. FIG. 20 illustrates the calculated quantum efficiency, assumed gain, and the calculated conversion efficiency as a function of N_{w} inside the corrugation for four different detector designs. For 60 QWs, the four detectors have the design characteristics (λ_{c}, η, CE, Γ) of (8.80 μm, 19.8%, 5.2%, 1.59 μm), (9.42 μm, 19.9%, 5.5%, 1.80 μm), (10.72 μm, 17.8%, 4.7%, 2.68 μm), and (11.65 μm, 18.6%, 5.2%, 3.04 μm), respectively, where Γ is the FWHM of the η spectrum. The calculated Γ of these detectors are generally narrower than that of the above experimental detectors having the same λ_{c}. Therefore the calculated peak η and CE are slightly higher than the experimental data shown.

To estimate the detector photocurrent, f/2 optics, an 8 μm cut-on atmospheric window, and 27° C. background were assumed. The NEΔT was evaluated using (11) with 2 ms integration time, a typical 900 noise electrons and zero spatial noise. FIG. 21 illustrates the calculated NEΔT of the four designed FPAs as a function of operating temperature assuming n_{rd}=900e⁻, and p=25 μm. FIG. 21 shows the respective NEΔT at different T. When, N_{w}>60, all the FPAs can achieve an NEΔT below 20 mK at T between 60-70 K. And there is no significant advantage in using N_{w}>60. With a finite n_{rd}, the shorter cutoff FPAs have an advantage over the longer cutoff FPAs only at high T. To achieve the best sensitivity, a longer cutoff FPA operating at a low T is needed. We should note that these high doping detectors are optimized for short integration times, with which the operating T tends to be lower. The optimization of FPAs towards a higher operating temperature will need a separate analysis.

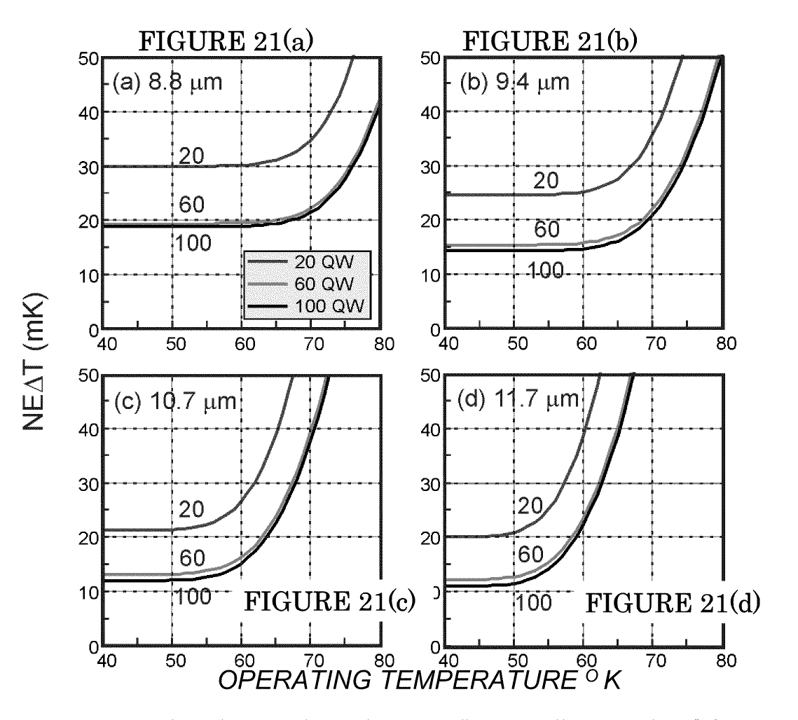

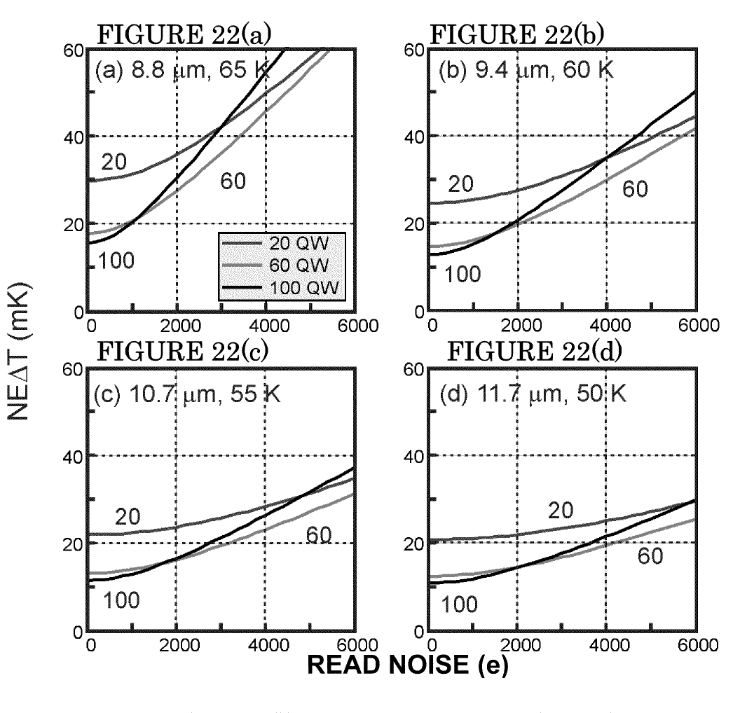

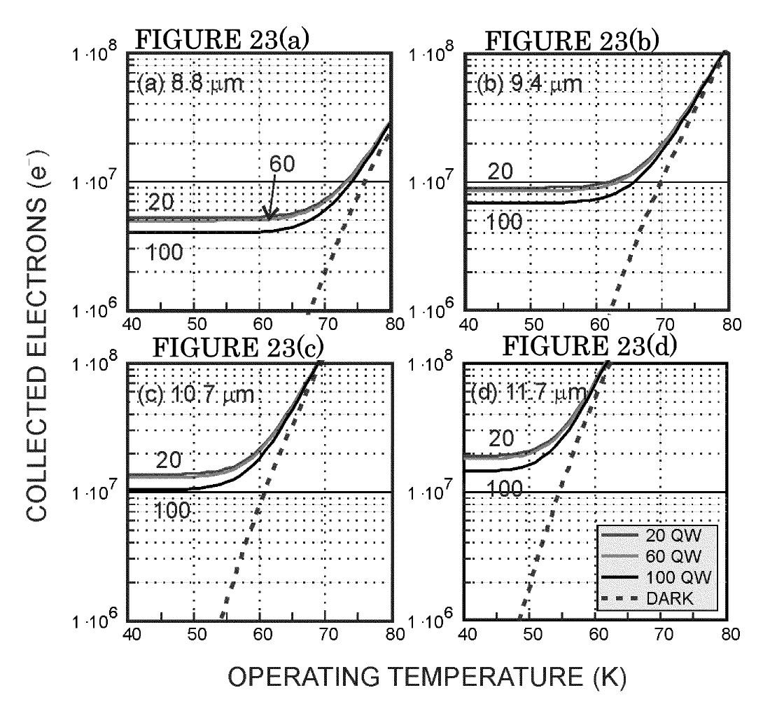

The effects of n_{rd} on NEΔT were further investigated and FIG. 22 shows the respective trend as a function of n_{rd}. FIG. 22 illustrates the projected NEΔT as a function of n_{rd} for the four FPA designs. FIG. 22 shows that the longer cutoff FPAs are more immune to readout and system noises than the shorter cutoff FPAs, albeit requiring a lower T. FIG. 22 also shows that when n_{rd} is very large, a 100-QW detector will not be as sensitive as a 20-QW detector. It can be understood from (11) that when n_{rd}>>2gNₜₒₜ, the overall noise of the system is dominated by the readout/system noises. In this case, NEΔT depends only on the signal but not the noise of the detector. The larger CE of the 20-QW detector will then be more advantageous. On the other hand, when n_{rd} is small, the detector signal to noise ratio is important. In this case, the lower noise of the 100-QW detector will give a better sensitivity. On balance, a 60-QW detector will give the best performance in most situations. To complete the analysis, FIG. 23 is a graphical illustration for the four FPA designs as a function of T revealing the number of collected electrons at different T if one is to achieve the sensitivity shown in FIG. 21. If the charge well capacity N_{c} of a ROIC is set to be twice of this value, the required respective N_{c} will be 11, 18, 28 and 39 Me⁻, respectively, for the four FPAs at BLIP.

In accordance with the principles of the present invention, the material and pixel structures for C-QWIP FPAs were substantially optimized, and produced a number of large format 1024×1024 FPAs. The experimental quantum efficiency of these FPAs was found to be in good agreement with the theoretical model. The largest η of 36% was obtained from a narrow band material with a large number of QWs. Despite this large peak value, the associated small gain and the large required voltage make the detector material less suitable for the current FPA implementation. For the presently available ROICs, a 60-QW design provides the best overall performance, with which η is typically about 18%. Together with a η bandwidth of 3 μm, C-QWIP FPAs are well suited for high speed imaging. A system analysis showed that FPAs with cutoffs between 9.4 and 10.7 μm are better for this purpose and should be able to provide a sensitivity less than 20 mK at 2 ms integration time with f/2 optics in the presence of 900e⁻ noise electrons. The pixel size of a C-QWIP can further be reduced as required for larger format FPAs. For example, with the same material α in FIG. 6B, a 15−(20−)μm pitch FPA will have a η₀ of 27.7 (32.3)%, which is only a small reduction from the 35.5% for a 25 μm pixel. In considering the fact that a smaller pixel will have a larger κ for the same active thickness, the difference in η will be even smaller, e.g. within 6% for a 60-QW structure. In addition, C-QWIPs structure has also been applied to voltage tunable two-color FPAs with promising results as reported in Choi, et al., “Voltage-tunable two-color corrugated-QWIP focal plane arrays,” IEEE Elect. Dev. Lett., vol. 29, pp. 1011-1013 (2008). Therefore, the development of C-QWIP technology has improved infrared detection and opens up a wide range of applications.

Possible uses for the present invention include a number of FPA cameras containing 1024×1024 pixels, with high resolution in long wavelength detection and high sensitivity in a number of tests. For example, a CLE CQ WIP FPA was found to have superior performance in detecting unmanned aerial vehicles in a detection contest, which consisted of 12 sensing teams using different technologies. The cameras are also used in ballistic missile intercept observations and obtained superior detailed video footages. In realizing the broadband characteristics of CLE C-QWIPs, NASA's Landsat program on an upcoming earth observing satellite, will tentatively include a Thermal Imaging Infrared Sensor that requires broadband infrared detectors. NASA has designated CLE C-QWIP FPAs to be the technology for this mission. This will be the first official space mission for QWIPs in NASA history. Because of its ability in generating large photocurrent needed for high speed imaging, Army Night Vision Lab together with L3, Inc. have chosen CLE C-QWIPs to be prime technology for its Objective Pilotage for Utility and Lift program. CLE C-QWIP FPAs can also be made into larger formats such as 4 megapixels or 16 megapixels and into two- or multi-color FPAs. The present invention is adaptable to many long wavelength applications in terms of availability, sensitivity, stability, reliability, resolution, and cost. The applications include night vision, all weather navigation, infrared astronomy, space exploration, earth resources exploration, environmental protection, geological survey, homeland security, industrial quality control, maintenance and diagnostics, and medical imaging etc.

Detector structure may be optimized to produce a number of large format focal plane arrays (FPAs). One-corrugation-per-pixel geometry may be adopted to increase the active detector volume and incorporate a composite cover layer to preserve the large sidewall reflectivity, which results in a large detector quantum efficiency. Also, the detector material structure may be optimized such as the final state energy, the doping density, and the number of quantum well periods to improve the FPA operation under the existing readout electronics. As a result, high FPA sensitivity has been achieved, and their characteristics are in agreement with the detector model. Based on this model, a systematic analysis on the FPA performance may be performed with a wide range of detector and system parameters. C-QWIP FPAs are capable of high speed imaging especially for those with longer cutoff wavelengths.

C-QWIP FPAs are inexpensive due to the standard batch processing, higher in sensitive due to efficient broadband light coupling, and higher in definition due to the smaller pixel size in the one corrugation per pixel geometry. C-QWIP coupling is also suitable for multi-color detection due to its wavelength-independent light coupling mechanism. CLE C-QWIP FPAs preserve the advantages of C-QWIPs in the FPA production environment, in which epoxy backfill is necessary in mating the detector array to the supporting electronic readout circuits.

Although various preferred embodiments of the present invention have been described herein in detail to provide for complete and clear disclosure, it will be appreciated by those skilled in the art, that variations may be made thereto without departing from the spirit of the invention.

It should be emphasized that the above-described embodiments are merely possible examples of implementations. Many variations and modifications may be made to the above-described embodiments. All such modifications and variations are intended to be included herein within the scope of the disclosure and protected by the following claims.

1. A quantum well infrared photodetector comprising:
a tunable voltage source;
first and second contacts operatively connected to the tunable voltage source;
a substantially-transparent substrate adapted to admit light;
first and second layers operatively connected to the first and second contacts;
a quantum well layer positioned between the first and second layers; light admitted through the substantially transparent substrate entering at least one of the first and second layers and passing through the quantum well layer;
at least one side wall adjacent to at least one of the first and second layers and the quantum well layer; the at least one side wall being substantially non-parallel to the incident light; the at least one sidewall comprising reflective layer which reflects light into the quantum well layer for absorption.

2. The photodetector of claim 1 wherein light is reflected by the at least one sidewall is substantially parallel to the quantum well layer for absorption by the quantum well layer.

3. The photodetector of claim 1 wherein at least sidewall comprise a metal layer and an electrically isolating layer positioned between the metal layer and the first layer, the second layer and the quantum well layer.

4. The photodetector of claim 2 wherein the metal layer is gold.

5. The photodetector of claim 3 wherein the electrically isolating layer is a dielectric.

6. The photodetector of claim 5 wherein the dielectric is magnesium fluoride.

7. The photodetector of claim 1 wherein the sidewalls are at an acute angle relative to the light admitted through the substantially transparent substrate.

8. The photodetector of claim 6 wherein the sidewalls are at a substantially forty-five degree angle to the light admitted through the substantially transparent substrate.

9. The photo detector of claim 1 wherein the light reflected by the at least one sidewall is substantially perpendicular to the light admitted through the substantially transparent substrate and at least a portion of the light is substantially parallel to the quantum well layer.

10. The photodetector of claim 1 wherein the thickness of the reflective layer is in the range of 30 to 1000 angstroms.

11. The photodetector of claim 3 wherein the thickness of the electrically isolating layer is in the range of 50 angstroms to 1 micron.

12. The photodetector of claim 1 wherein the first, second and quantum layers are deposited by epitaxy.

13. The photodetector of claim 1 wherein the first and second layers comprises a top contact layer having a slightly steeper sidewall angle than the quantum well layer which is inclined at approximately 45° relative to the plane of the first and second layers, with the average sidewall angle of the first, second, and quantum well layers being approximately 50°.

14. The photodetector of claim 1 wherein the at least one side wall reflects a wide range of wavelengths resulting in broadband detection and the voltage-tunable characteristics of the VT-QWIP results in multi-color detection.

15. A plurality of quantum well infrared photodetectors arranged in a focal plane array device, each quantum well infrared photodetector comprising:
a tunable voltage source;
first and second contacts operatively connected to the tunable voltage source;
a substantially-transparent substrate adapted to admit light;
first and second layers operatively connected to the first and second contacts;
a quantum well layer positioned between the first and second layers; light admitted through the substantially transparent substrate entering at least one of the first and second layers and passing through the quantum well layer;
at least one side wall adjacent to at least one of the first and second layers and the quantum well layer; the at least one side wall being substantially non-parallel to the incident light; the at least one sidewall comprising reflective layer which reflects light into the quantum well layer for absorption.

16. The device of claim 15 further comprising a bottom layer coupled to the substantially-transparent substrate, the bottom layer being substantially parallel to the substantially transparent substrate; side surfaces extending along the sides of the first, second and quantum layers, each side surface being substantially non-parallel to an opposing side surface; and first-wavelength quantum-well infrared photodetector elements, each first-wavelength QWIP element being a first superlattice of quantum wells adapted to detect energy at a first range of wavelengths when the voltage source supplies the positive bias; and second-wavelength QWIP elements, each second-wavelength QWIP element being a second superlattice of quantum wells adapted to detect energy at a second range of wavelengths when the voltage source supplies the negative bias, the second range of wavelengths being different from the first range of wavelengths; and wherein an energy relaxation layer is interposed between the first superlattice of quantum wells and the second superlattice of quantum wells.

17. The device of claim 16 further comprising a processor coupled to the focal plane array device, the processor being configured to generate a first-wavelength two-dimensional image, the first-wavelength two-dimensional image being generated from the photocurrents proportional to the detected energy at the first range of wavelengths, the processor further being configured to generate a second-wavelength two-dimensional image, the second-wavelength two-dimensional image being generated from the photocurrents proportional to the detected energy at the second range of wavelengths.

18. A method of improving the efficiency of a corrugated-quantum well infrared photodetector device having first and second contact layers and a quantum well layer; the method comprising;
forming a first sidewall layer on the sidewalls of the corrugated quantum well infrared photodetector;
forming a second sidewall layer on the sidewalls of the corrugated quantum well infrared photodetector; the second sidewall layer being formed of a reflective material and the first sidewall layer operating to electrically isolate the reflective material from at least one of the first and second contact layers;
whereby the reflective metal operates to reflect light rays into corrugated quantum well infrared photodetector device and to substantially prevent infrared rays in environment from entering through the sidewalls.

19. The method of claim 18 wherein the first side wall layer comprises magnesium fluoride and the second sidewall layer comprises gold.

20. The method of claim 18 wherein epoxy is first removed from the sidewalls of the corrugated quantum well infrared photodetector before the formation of the first and second sidewall layers.
